(19) United States
(12) Patent Application Publication
(10) Pub. No.: US 2026/0160846 A1
(43) Pub. Date: Jun. 11, 2026

(54) Devices and Systems for Sensing and Locating Radio Frequency Signals

(71) Applicant: Rutgers, The State University of New Jersey, New Brunswick, NJ (US)

(72) Inventors: Ranjan Kumar Patel, New Brunswick, NJ (US); Narayan B. Mandayam, East Brunswick, NJ (US); Ivan Seskar, North Brunswick, NJ (US); Shriram Ramanathan, Princeton, NJ (US)

(21) Appl. No.: 19/415,186

(22) Filed: Dec. 10, 2025

Related U.S. Application Data
(60) Provisional application No. 63/730,145, filed on Dec. 10, 2024.

(51) Int. Cl. G01S 3/12; G01R 27/08; G01S 3/04; H04B 17/27; H04B 17/391

(52) U.S. Cl. CPC G01S 3/12; G01R 27/08; G01S 3/043; H04B 17/27; H04B 17/391

(57) ABSTRACT

Embodiments are directed to methods and systems for sensing radio frequency (RF) signals. The system includes a quantum material film having an electrical resistance, and a source meter coupled to the quantum material film. The source meter is configured to: (i) measure the electrical resistance of the quantum material film, and (ii) output the measured electrical resistance of the quantum material film. A change in the output of the measured electrical resistance indicates a presence of an RF signal.

### RELATED APPLICATION

This application claims the benefit of U.S. Provisional Application No. 63/730,145, filed on Dec. 10, 2024. The entire teachings of the above application are incorporated herein by reference.

### BACKGROUND

Radio frequency (RF) sensing technology has revolutionized various fields, including wireless communication, radar systems, medical imaging, and environmental monitoring, amongst other examples. Traditional RF sensing architectures follow a multi-stage process, converting RF signals to intermediate frequency (IF) and then to baseband for signal processing. While this RF-to-IF-to-baseband approach offers significant advantages in terms of signal filtering, amplification, and frequency management, this existing approach comes with limitations such as increased complexity, power consumption, and the need for high-precision components, especially in scenarios requiring rapid signal detection and low-power operation.

### SUMMARY

Embodiments solve the problems of existing radio frequency (RF) sensing methodologies and provide improved systems and methods for sensing RF signals.

An example embodiment is directed toward a system for sensing RF signals. The system includes a quantum material film having an electrical resistance, and a source meter coupled to the quantum material film. The source meter is configured to: (i) measure the electrical resistance of the quantum material film and (ii) output the measured electrical resistance of the quantum material film. A change in the output of the measured electrical resistance indicates a presence of an RF signal.

An embodiment of the system further includes a first electrode and a second electrode deposited on the quantum material film, wherein the first electrode and the second electrode are separated by a distance and the source meter is coupled to the quantum material film via the first electrode and the second electrode. In such an embodiment, the measured electrical resistance may be a function of the distance between the electrodes. Further, according to an embodiment, at least one of the first electrode and the second electrode comprises at least one of gold, chromium, titanium, TiN, platinum, and nickel.

An embodiment further includes a heating element configured to heat the quantum material film to a configured temperature. In such an embodiment, the measured electrical resistance may be a function of the configured temperature.

In an embodiment, the RF signal is between 0.1 gigahertz (GHz) and 100 GHz.

In another embodiment, the quantum material film is at least one of: NdNiO3, H-doped NdNiO3, LaNiO3, SmNiO3, H-doped SmNiO3, PrNiO3, EuNiO3, Sm-doped NdNiO₃, Sm-doped PrNiO₃, H-doped PrNiO₃, VO2, Cr-doped VO₂, W-doped VO₂, VOₓ, V2O5, V2O3, LaCoO3, Sr-doped LaCoO3, NbO2, W03, NiO, LaMnO3, Sr-doped LaMnO3, and LaTiO3.

In an embodiment, the quantum material film is between 1 nanometer (nm) and 100 millimeters (mm) thick.

In another embodiment, the quantum material film and source meter are integrated into a portable device. According to an example embodiment, the portable device is at least one of: configured to be carried on a person, mounted on a drone, mounted on a vehicle, and mounted on a robot.

An embodiment includes a plurality of RF sensing devices. Each RF sensing device of the plurality includes a given quantum material film having a given electrical resistance and a respective source meter coupled to the given quantum material film. Each respective source meter is configured to: (i) measure the given electrical resistance of the given quantum material film and (ii) output the measured given electrical resistance of the given quantum material film, wherein a change in the output of the measured given electrical resistance indicates a presence of one or more RF signals.

Another embodiment which includes the plurality of RF sensing devices may further include a processor and a memory with computer code instructions stored thereon. The processor and the memory with the computer code instructions stored thereon, are configured to cause the system to analyze, via a machine learning engine, each measured given electrical resistance. A result of the analyzing may be at least one of: an indication of frequency of the one or more RF signals, an indication of signal strength of the one or more RF signals, an indication of direction of the one or more RF signals, and an indication of spectrum of the one or more RF signals.

Another system embodiment includes a processor, and a memory with computer code instructions stored thereon. The processor and the memory with the computer code instructions stored thereon are configured to cause the system to analyze, via a machine learning engine, the output measured electrical resistance. In an embodiment, a result of the analyzing is at least one of: an indication of frequency of the RF signal, an indication of signal strength of the RF signal, an indication of direction of the RF signal, and an indication of spectrum of the RF signal.

Another embodiment is directed toward a method for sensing radio frequency (RF) signals. The method includes (i) receiving one or more signals at a quantum material film having an electrical resistance, (ii) measuring, using a source meter coupled to the quantum material film, the electrical resistance of the quantum material film, and (iii) outputting, from the source meter, the measured electrical resistance of the quantum material film. A change in the output of the measured electrical resistance indicates a presence of an RF signal from amongst the one or more signals.

An embodiment includes configuring a distance between a first electrode and a second electrode deposited on the quantum material film, wherein the source meter is coupled to the quantum material film via the first electrode and the second electrode. In such an embodiment, the measured electrical resistance may be a function of the configured distance.

Another embodiment includes heating the quantum material film to a configured temperature. According to an example embodiment, the measured electrical resistance is a function of the configured temperature.

In an embodiment, the RF signal is between 0.1 gigahertz (GHz) and 100 GHz.

The method, according to an embodiment, further includes integrating the quantum material film and source meter into a portable device.

Another example embodiment includes deploying a plurality of RF sensing devices. Each deployed RF sensing device is configured to (i) receive one or more respective signals at a given quantum material film having a given electrical resistance, (ii) measure, using a respective source meter coupled to the given quantum material film, the given electrical resistance of the given quantum material film, and (iii) output, from the respective source meter, the measured given electrical resistance of the given quantum material film. In such an embodiment, a change in the output of the measured given electrical resistance indicates a presence of at least one RF signal amongst the one or more respective signals.

Yet another embodiment includes analyzing, via a machine learning engine, each measured given electrical resistance. In an embodiment, a result of the analyzing is at least one of: an indication of frequency of the at least one RF signal, an indication of signal strength of the at least one RF signal, an indication of direction of the at least one RF signal, and an indication of spectrum of the at least one RF signal.

An embodiment analyzes, via a machine learning engine, the output measured electrical resistance. In an embodiment, a result of the analyzing is at least one of: an indication of frequency of the RF signal, an indication of signal strength of the RF signal, an indication of direction of the RF signal, and an indication of spectrum of the RF signal.

It is noted that embodiments of the methods and systems may be configured to implement any embodiments, or combination of embodiments, described herein.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a schematic representation of a system for RF sensing, according to an embodiment.

FIG. 2 is a flow diagram for a method of sensing RF signals, according to an embodiment.

FIGS. 3A-3E are plots illustrating experimental results from embodiments for sensing RF signals.

FIGS. 4A and 4B show plots illustrating relative percentage change in resistance of VO₂ and VOₓ films under irradiation of a RF signal at different temperatures.

FIGS. 4C and 4D show plots illustrating temporal evolution of the maximum relative percentage change in resistance of VO₂ and VOₓ films.

FIGS. 4E-4G show plots illustrating the change in resistance with the application of RF radiation at different temperatures for thin films of NdNiO3, VOₓ, and VO₂ films.

FIG. 5A shows a plot illustrating relative percentage change in resistance of a VO₂ quantum material film subject to a RF signal at different gain values, according to an embodiment.

FIG. 5B shows plots illustrating received power and relative percentage change in resistance of a VO₂ quantum material film under an RF signal at different gain values, respectively, according to an embodiment.

FIG. 5C shows a plot illustrating relative percentage change in resistance of a VO₂ quantum material film under an RF signal from different distances, according to an embodiment.

FIG. 5D shows plots illustrating received power and relative percentage change in resistance of a VO₂ quantum material film under an RF signal at different distances, respectively, according to an embodiment.

FIG. 6 is a plot illustrating relative percentage change in resistance of VO₂ quantum material films with different separations of electrodes subject to a 2.4 GHz RF signal with a gain of 100 at 73° C. for five minutes at a distance of 8 cm, according to an embodiment.

FIGS. 7A-7E show respective plots illustrating resistance of VO₂ quantum material films with different electrode separations as a function of time subject to a 2.4 GHz RF signal with a gain of 100 at 73° C. at a distance of 8 cm, according to embodiments.

FIG. 7F shows a plot illustrating the time constant as a function of electrode separation of the VO₂ film subject to a 2.4 GHZ RF signal with a gain of 100 at 73° C. at a distance of 8 cm, according to embodiments.

FIG. 8 is a schematic diagram illustrating an embodiment that implements and deploys a plurality of RF sensing devices.

FIG. 9 is a photograph of an experimental setup where RF waves concentrate onto an RF sensing device, according to an embodiment, placed on a probe station.

FIG. 10 is a photograph of a calibration setup used to measure received power of an RF wave from an RF antenna using a spectrum analyzer.

FIGS. 11A-11C are plots illustrating resistance sensing of embodiments as a function of temperature of a VO₂ quantum material film with and without being subjected to RF radiation.

FIG. 12 is a plot illustrating an X-ray diffraction (XRD) scan of a VO₂ quantum material film before and after exposure to radiation of an RF signal of 2.4 GHz for 5 minutes.

FIG. 13 is a plot illustrating relative percentage change in resistance of two VOₓ quantum material films over time while subjected to a 2.4 GHz RF signal with 100 gain for 5 minutes at 8 cm and at 73° C.

FIGS. 14A-14D show respective plots illustrating relative percentage change in resistance of a VO₂ quantum material film while exposed to an RF signals of varying frequencies with 100 gain for 5 minutes at 8 cm and at 73° C.

FIG. 15 is a plot illustrating relative percentage change in resistance of a VO₂ quantum material film with 15 μm electrode separation at 73° C. over time using different applied voltages under a 2.4 GHz RF radiation with a gain value of 100 from a distance of 8 cm.

FIG. 16 is a plot illustrating relative percentage change in resistance at different gain values of a VO₂ quantum material film under RF radiation (2.4 GHz at 73° C. for 5 minutes from a distance of 8 cm) with an applied voltage.

FIGS. 17A-17E show respective plots illustrating resistance of VO₂ quantum material film devices, according to embodiments, with different channel gaps (between electrodes) as a function of time while subjected to a 2.4 GHz RF signal at 73° C. for 5 minutes from a distance of 8 cm.

FIG. 18 is a schematic view of a computer network in which embodiments may be implemented.

FIG. 19 is a block diagram illustrating an embodiment of a computer node in the computer network of FIG. 18.

### DETAILED DESCRIPTION

A description of example embodiments follows.

The radio frequency (RF) radiation spectrum is central to wireless and radar systems among other high-frequency device technologies. Embodiments disclosed herein sense RF signals in a wide frequency range. Embodiments can also be tuned for particular frequency ranges, such as the technologically relevant 2.4 Gigahertz (GHz) range. Embodiments can utilize quantum material films, such as vanadium dioxide (VO₂), a quantum material that has garnered significant interest for its insulator-to-metal transition. The electrical resistance of both stoichiometric and off-stoichiometric vanadium oxide films can be modulated with RF wave exposures from a distance. The response of the materials to the RF waves can be enhanced by either increasing the power received by the material or reducing channel separation, i.e., distance between electrodes on the material. A significant ˜73% drop in resistance can be observed with a 5 micrometer (μm) channel gap of the VO₂ film, in embodiments, at a characteristic response time of 16 microseconds (μs). Peak sensitivity, according to an embodiment, is proximal to the phase-transition-temperature boundary that can be engineered via doping and crystal chemistry. Dynamic sensing measurements highlight the films' rapid response and broad-spectrum sensitivity. Engineering electronic phase boundaries in correlated electron systems offer new capabilities in emerging communication technologies.

Sensing of RF signals and wireless spectrum has increasingly become essential for a wide variety of uses. These uses range from the classical need for spectrum sensing in cognitive radio (CR) ecosystems to opportunistically use the available spectrum, to the more generic uses of RF signals for a variety of applications supported by the Internet of Things (IOT) ecosystem. In CR scenarios, spectrum sensing has been used to create radio maps that allow secondary spectrum users to exploit available spectrum holes and peacefully coexist with primary (incumbent) users of spectrum [1]. In the IOT ecosystem, RF signal sensing has been used for a variety of applications, e.g., environmental monitoring, healthcare, and advanced manufacturing [2], to name a few. Further, the developments in the evolution of sixth-generation wireless technologies have underscored the importance of sensing by seeking to integrate communications and sensing in a joint framework [3].

The need for RF sensing without necessarily using complex (and often frequency-specific) signal processing is attractive. Further, having such sensing accomplished at high speeds is particularly relevant not only for supporting low-latency communications but also for enabling follow-up actions related possibly to network security and control. While the sensing methodologies disclosed herein are applicable even in the far field, near-field sensing has become increasingly relevant with the emergence of the IOT ecosystem, with high densities of devices in close geographical proximity to each other for various machine-to-machine communications scenarios, including sensors in body and personal area networks. Therefore, there is a need for RF sensing that utilizes a novel materials-based sensing approach in the near field that can be used seamlessly in a wide variety of scenarios. Embodiments provide such functionality.

Materials exhibiting electronic phase transitions are well suited for sensing applications. Vanadium dioxide (VO₂), a prototypical quantum material characterized by its insulator-to-metal transition (IMT) near room temperature, has been explored as a switch [4-6] and sensor for chemical, thermal, and terahertz detection [7-10]. The IMT characteristics can be further modified by utilizing an off-stoichiometric vanadium oxide compound, denoted as VOₓ [11-13]. Simultaneously, the V:O materials family is recognized for its efficacy as a bolometer [14-16], exemplifying the versatile applications of such materials in sensing technologies. Here, embodiments demonstrate the effect of RF waves on VO₂ and off-stoichiometric VOₓ films on a sapphire single crystal substrate (c-Al₂O₃ (0001)) by varying different parameters, such as the temperature, frequency, device geometry, the distance of the film from the RF antenna, and the gain and power of the RF waves. The results described herein particularly focus on the 2.4-GHz frequency range due to its importance in wireless communications, however, embodiments are not limited to sensing RF signals in the 2.6 GHz range and, instead, embodiments can sense RF signals in a variety of ranges, e.g., 0.1 gigahertz (GHz) and 100 GHz. The experimental results suggest that embodiments provide improved RF sensors and contribute to advancements in future Wi-Fi technologies, amongst other applications.

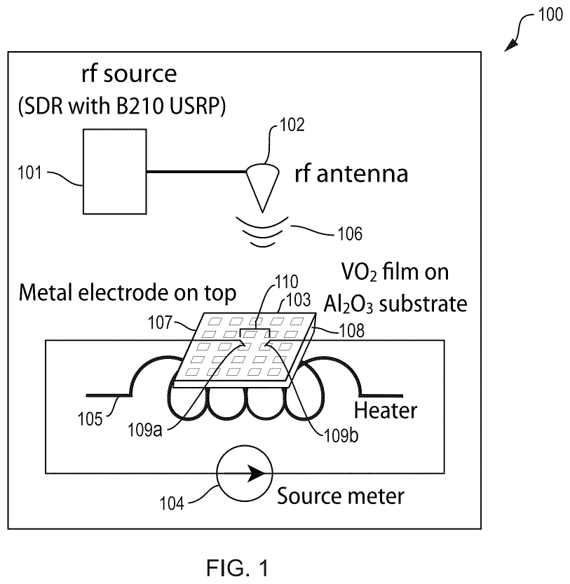

FIG. 1 is a diagram illustrating a schematic representation of an RF sensing system 100 according to an embodiment. The system 100 includes a RF source 101 (for example, Software Defined Radio (SDR) with B210 Universal Software Radio Peripheral (USRP)) coupled with a RF antenna 102 to produce an example RF signal 106. The RF signal 106 of FIG. 1 is an example RF signal and is illustrative of an ambient propagating signal in an environment in which the RF sensing device 100 is operating. The RF sensing system 100 includes a sensing device (collectively 103) that includes a quantum film 107, e.g., VO₂, disposed on a substrate 108, e.g., an Al₂O₃ substrate. The device 103 is coupled to a source meter 104 via electrodes 109a-b disposed on the substrate 108 and separated by a distance 110. This known distance alters the resistance measured by the source meter, as the resistance of the quantum material film is a function of the length of quantum material film being measured. The system 100 also includes a heater 105 configured to heat the device 103, i.e., the quantum film 107 disposed on the substrate 108.

In the system 100 the quantum material film 107 has an electrical resistance and the source meter 104 is configured to: (i) measure the electrical resistance of the quantum material film 107 and (ii) output, e.g., via a wired or wireless connection to a computing device, the measured electrical resistance of the quantum material film 107. A change in the output of the measured electrical resistance indicates a presence of an RF signal, e.g., 106.

In an embodiment, the source meter 104 is coupled to the quantum material film 107 via the electrodes 109a and 109b. In such an embodiment, the measured electrical resistance may be a function of the distance 110 between the electrodes 109a-b. Further, according to an embodiment, at least one of the electrodes 109a-b comprises at least one of gold, chromium, titanium, TiN, platinum, and nickel.

In an embodiment the heating element 105 is configured to heat the quantum material film 107 to a configured temperature. In such an embodiment, the measured electrical resistance may be a function of the configured temperature. Further, the resistance of the quantum material film may also be a function of the temperature of the quantum material film. The heater may be integrated into the chip using resistive heating wire fabrication.

In an embodiment, the RF signal sensed by the system 100 is between 0.1 gigahertz (GHz) and 100 GHz.

In another embodiment, the quantum material film 107 is at least one of: NdNiO3, H-doped NdNiO3, LaNiO3, SmNiO3, H-doped SmNiO3, PrNiO3, EuNiO3, Sm-doped NdNiO₃, Sm-doped PrNiO₃, H-doped PrNiO₃, VO2, Cr-doped VO₂, W-doped VO₂, VOₓ, V2O5, V2O3, LaCoO3, Sr-doped LaCoO3, NbO2, W03, NiO, LaMnO3, Sr-doped LaMnO3, and LaTiO3. These materials may be grown in bulk polycrystalline form by solid-state synthesis, in single crystal form by floating zone, flux growth, Czochralski, hydrothermal methods, etc., or in thin film form by atomic layer deposition (ALD), pulsed laser deposition (PLD), molecular beam epitaxy (MBE), spin coating, thermal evaporation, electron beam evaporation, chemical vapor deposition, and RF/dc/magnetron sputtering.

In an embodiment, the quantum material film 107 is between 1 nanometer (nm) and 100 millimeters (mm) thick.

In another embodiment, the quantum material film 107 and source meter 104 are integrated into a portable device. According to an example embodiment, the portable device is at least one of: configured to be carried on a person, mounted on a drone, mounted on a vehicle, and mounted on a robot.

The system 100 may further include a processor, and a memory with computer code instructions stored thereon. The processor and the memory with the computer code instructions stored thereon are configured to cause the system 100 to analyze, e.g., via a machine learning engine, the output measured electrical resistance (from the source meter 104). In an embodiment, a result of the analyzing is at least one of: an indication of frequency of the RF signal, an indication of signal strength of the RF signal, an indication of direction of the RF signal, and an indication of spectrum of the RF signal.

In some embodiments, there may be a plurality of RF sensing devices, wherein each of the plurality of RF sensing devices are configured to implement the method 200 (disclosed herein). Embodiments of the device may receive RF signals and transmit the data to a computer either through wired connections or wirelessly via an antenna. By analyzing the resistance variations, the system may accurately map critical parameters, including the frequency of RF radiation, signal strength, and the direction of incoming radiation allowing precise and real-time spectrum monitoring, making the device suitable for applications in defense, communications, and security.

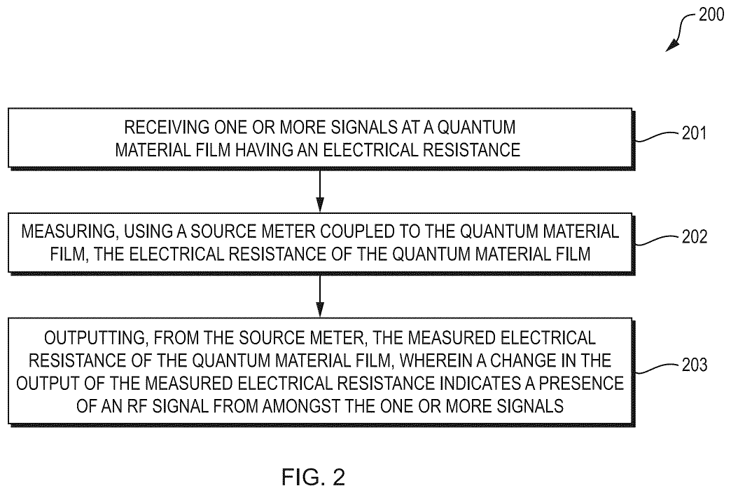

FIG. 2 is a flow diagram of a method 200 of sensing RF signals, according to an embodiment. The method 200 begins by receiving 201 one or more signals at a quantum material film having an electrical resistance. To continue, the method 200 measures 202, using a source meter coupled to the quantum material film, the electrical resistance of the quantum material film. In turn, the method 200 outputs 203, from the source meter, the measured electrical resistance of the quantum material film. In the method 200, a change in the output of the measured electrical resistance indicates a presence of an RF signal from amongst the one or more signals.

An embodiment of the method 200 includes configuring a distance between a first electrode and a second electrode deposited on the quantum material film, wherein the source meter is coupled to the quantum material film via the first electrode and the second electrode. In such an embodiment, the measured 202 electrical resistance may be a function of the configured distance.

Another example embodiment of the method 200 includes deploying a plurality of RF sensing devices. Each deployed RF sensing device is configured to (i) receive one or more respective signals at a given quantum material film having a given electrical resistance, (ii) measure, using a respective source meter coupled to the given quantum material film, the given electrical resistance of the given quantum material film, and (iii) output, from the respective source meter, the measured given electrical resistance of the given quantum material film. In such an embodiment, a change in the output of the measured given electrical resistance indicates a presence of at least one RF signal amongst the one or more respective signals.

### Experimental Details

Hereinbelow, experimental results of embodiments are described as well as embodiment set-ups used to obtain the results.

For example, embodiments used to generate the experimental results utilized VO₂ and off-stoichiometric VOₓ films of thickness ˜40 nanometers (nm) that were grown on c-Al₂O₃ (0001) substrates by a RF magnetron sputtering (AJA International) system [11]. A ceramic V₂O₅ target of 99.9% purity was used with 100-Watts RF power. In an embodiment, a V₂O₅ target was pre-sputtered for 5 minutes before the deposition. During deposition, the pressure was maintained at 5 millitorr (mTorr) by introducing 49.5 standard cubic centimeters per minute (SCCM) argon (Ar) and 0.5-SCCM O₂—Ar (10%-90%) gas mix for VO₂ growth; whereas 49.9-SCCM Ar and 0.1-SCCM O₂ gases were used for VOₓ growth. The substrate temperature was 650° C., and the substrate holder was rotated at 40 revolutions per minute (RPM) during the growth to maintain the homogeneity of the sample.

Postdeposition, the substrate was cooled down to room temperature at the growth pressure. Platinum (Pt) and Nickel (Ni) electrodes were deposited (using sputtering) at room temperature (˜22° C.) on VO₂ and VOₓ films using a shadow mask, respectively. This was carried out to facilitate electrical measurements across millimeter-scale junctions, with channel separations of 300 μm, 900 μm, 2100 μm, and 4500 μm (and a channel width of 300 μm). To investigate microscale junctions, VO₂ devices with 5 μm, 15 μm, 25 μm, and 30 μm separation between the electrodes (and a channel width of 5 μm) were fabricated through photolithography using a photoresist of, for example, AZ 1518, as the masking layer for the process. A maskless aligner, for example the Heidelberg MLA150 Maskless Aligner, was used to write the electrode pattern [17]. A 100-nm-thick layer of Pt was deposited through electron-beam evaporation and subsequently lifted off by using, for example, PG-Remover, at 80° C.

The X-ray diffraction (XRD) patterns of the substrate and as-deposited films were recorded using a laboratory-based Panalytical Xpert diffractometer with a copper (Cu) source. Rutherford backscattering spectroscopy (RBS) measurements were performed to estimate the stoichiometry by using a 1.7 megavolt (MV) tandem accelerator with a 2.3 megaelectron-volt (MeV) He²+ ion beam of diameter 2 mm. The scattering angle of the detector was 163°, and the resolution of the detector was 18 kiloelectron-volt (keV). The RBS data were analyzed by using for example, the SIMNRA program [18]. The direct current (DC) transport measurements were performed on a probe station using a source meter, for example a Keithley 2635A source meter, and the temperature was controlled by using a Quiet CHUCK DC Hot Chuck system (See FIG. 1 discussed herein, see also [19]). The electrical contacts were made by contacting the micromanipulator tips of the probe station to the metal electrodes directly. The resistance was measured by taking the slope of the current (I)-volt (V) data taken between −0.05 and +0.05 V in a two-probe configuration. The time-resolved measurements were performed using a source meter, for example the Keithley 2461 source meter, by applying a constant voltage of +0.05 V.

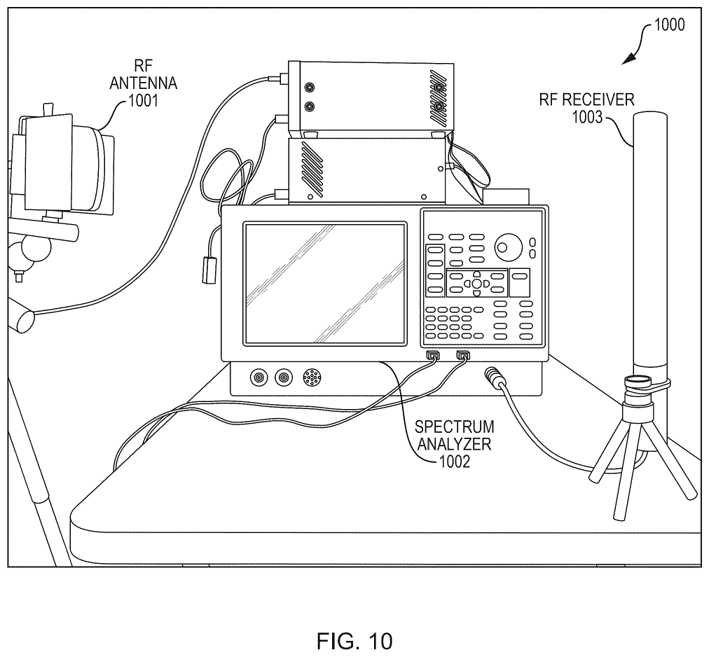

In the RF measurement setup, a Software Defined Radio (SDR) platform, for example, the X86-based SDR platform (Quad-core i7 embeddedPC) was used and equipped with a Universal Software Radio Peripheral (USRP), for example, a B210 USRP and a directional antenna. The USRP, interfaced with the SDR platform, utilized User Hardware Driver (UHD) tools for the precise generation and control of RF waveforms. To augment the system, it was connected to the output of the USRP so as to enhance the emitted RF signal strength. This setup was instrumental in effectively exciting VO₂ and VOₓ films on c-Al₂O₃ substrates. The waveform used was a narrowband sine wave, with the gain values disclosed herein corresponding to the UHD tx_waveform utility command line gain argument. The directional antenna, in conjunction with the amplified signal from the power amplifier, focused the RF energy onto the samples in the laboratory (See FIG. 1 discussed herein, see also [19]). The software-based waveform configuration enabled precise control over key parameters, such as frequency and power. The setup was calibrated with a spectrum analyzer in the COSMOS testbed environment at WINLAB [20], measuring the received power by the films at various distances from the SDR setup and with different gain values (See FIG. 10 discussed herein, see also [19]). The measurements were done in the near-field regime. The “near-field” context in these experiments is defined by the close proximity between the antenna and the device, where the electromagnetic interactions are governed by near-field principles, including considerations of the first Fresnel zone, rather than the propagation-dominated interactions typical of far-field contexts.

### Results and Discussion

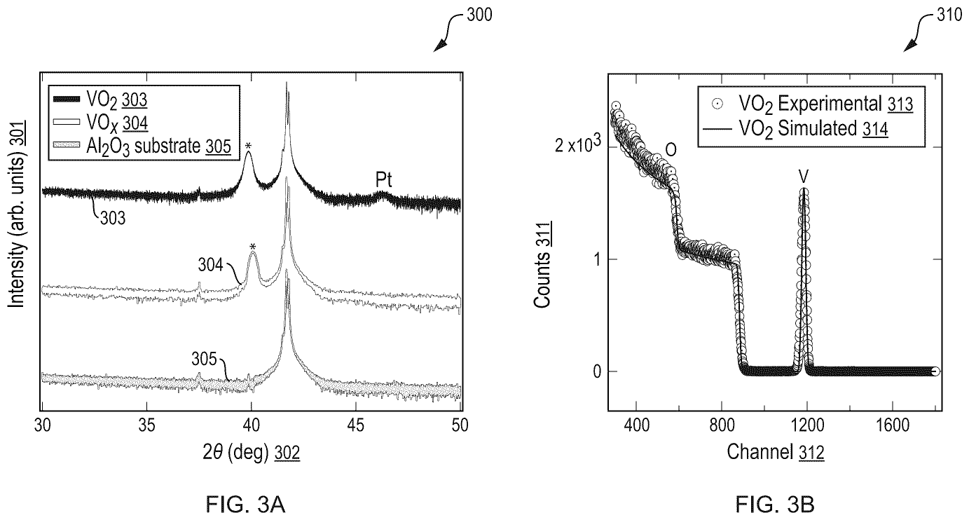

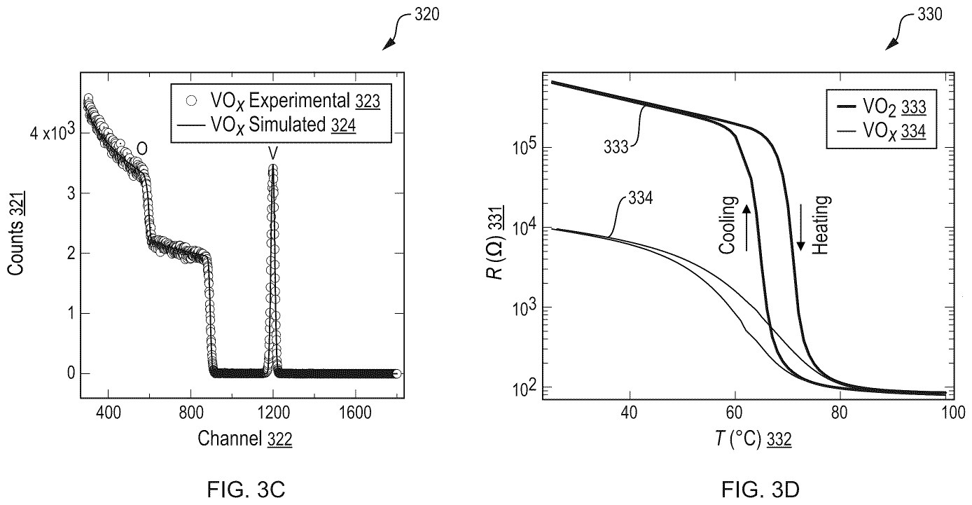

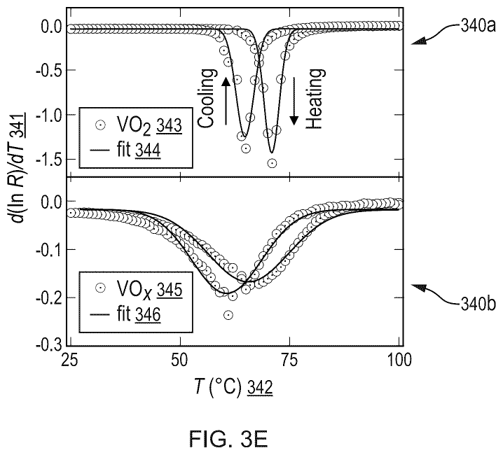

In order to check the structural quality of the VO₂ and VOₓ films grown on sapphire substrates by RF sputtering, 2θ versus ω diffraction scans were recorded. For comparison, the XRD pattern of the single-crystal sapphire substrate was also measured. The XRD scans of the VO₂ and VOₓ films consist of a broader film peak (marked by * in FIG. 3A discussed herein) and a sharp substrate peak (2θ=41.68°) [21], where the substrate peak arises due to the (0006) reflection of the c-Al₂O₃. For the VO₂ film, a well-defined XRD peak corresponding to the monoclinic (020) phase (crystal plane) [21] was observed at 20=39.86°. From these data, the lattice distance (bm) was estimated (bm=4.52 angstroms (Å)), which is similar to the respective literature value of expected monoclinic VO₂ [22]. For the off-stoichiometric sample (VOₓ), the XRD peak was observed at 2θ=40.08°, which indicates a value of bm=4.5 Å. This slight shift of the XRD peak is related to the oxygen non-stoichiometry in the VOₓ film [23,24]. Apart from this peak shift, no new diffraction peaks are observed.

FIGS. 3A-3E show plots 300, 310, 320, 330, and 340, respectively, illustrating experimental results of sensing RF signals using embodiments. FIG. 3A is a plot 300 illustrating the results of 2θ versus ω diffraction scans for the VO₂ 303 film, VOₓ 304 film, and Al₂O₃ 305 substrate, respectively. The plot 300 illustrate resulting intensity 301 versus 2θ 302.

Additionally, to determine the elemental composition of the VO₂ and VOₓ films, i.e., the ratio of Vanadium to Oxygen in the material, Rutherford backscattering spectroscopy experiments were performed. In RBS, the qualitative determination of the areal density of the elements is possible by analyzing the intensity and energy of the backscattered He²+ ions from the sample within 1-2% accuracy [25]. FIGS. 3B and 3C show the RBS analysis data of VO₂ and VOₓ films, respectively; and the values obtained from the analysis are summarized in Table I below. Specifically, FIGS. 3B and 3C show plots 310 and 320 illustrating experimental and simulated Rutherford backscattering spectroscopy data for VO₂, and VOₓ, respectively. FIG. 3B is a plot 310 of Rutherford backscattering spectroscopy data in counts 311 versus channel 312 (i.e., the energy of the backscattered ion beam—each channel corresponds to an energy) for VO₂ as simulated 314 and as measured 313 experimentally. FIG. 3C is a plot 320 of Rutherford backscattering spectroscopy data in counts 321 versus channel 322 for VOₓ as simulated 324 and as measured 323 experimentally. For VO₂ and VOₓ films, the ratio of the spatially averaged areal density of vanadium to oxygen (V:O) are estimated as 1:2 and 1:1.7, respectively.

TABLE I
Summary of RBS and Transport Data

| | V (×10¹⁵ | O (×10¹⁵ | T_{IMT}^{h} | T_{IMT}^{c} |
|---|---|---|---|---|
| Sample | atoms/cm²) | atoms/cm²) | (° C.) | (° C.) |
| VO₂ | 101.9 | 204.1 | 70.6 | 64.1 |
| VOx | 103.6 | 176.4 | 64.3 | 59.4 |

Following the structural measurements, the electrical transport properties of the films was investigated. As previously reported [11, 21, 22, 26, 27], a VO₂ film on Al₂O₃ substrate undergoes an insulator-to-metal transition accompanied by a structural change from monoclinic to tetragonal rutile structure upon increasing the temperature. FIG. 3D is a plot 330 of temperature-dependent resistance 331 of VO₂ 333 and VOₓ 334 films on c-Al₂O₃ substrate versus temperature 332. For the stoichiometric VO₂ sample 333, the resistance 331 changes abruptly by around four orders of magnitude, which verifies the high quality of the film. On the other hand, the VOₓ film 334 undergoes a resistance change of around two orders of magnitude. This is characteristic of oxygen-deficient vanadium oxides that show suppressed insulating state resistance and transition temperature.

The IMT temperature was calculated by plotting (as shown in the plots 340a and 340b of FIG. 3E) d(ln R) dT 341 as a function of temperature 342 and taking the maximum magnitude after fitting with a Gaussian curve. FIG. 3E shows plots 340a and 340b illustrating Gaussian fitting of the differential curves of resistance 341 versus temperature 342. The plot 340a includes the differential curve of resistance for VO₂ 343 and the fit 344. Similarly, the plot 340b includes the differential curve of resistance for VOₓ 345 and the fit 346. The plots 340a and 340b can be used to extract the IMT for the VO₂ 343, and VOₓ 345 films. The IMT of the VO₂ in heating

$$( {T}_{IMT}^{h} \sim 70.6 ° C . )$$

and cooling

$$( {T}_{IMT}^{c} \sim 64.1 ° C . )$$

runs are higher compared to that of the bulk VO₂

$$( {T}_{IMT}^{h} \sim 68 ° C . )$$

and is related to the tensile strain [22, 28, 29]. Again, for the off-stoichiometric VOₓ sample,

$${T}_{IMT}^{h} and {T}_{IMT}^{c}$$

are calculated as 64.3° C. and 59.4° C., respectively, which are lower compared to that of the stoichiometric VO₂ sample.

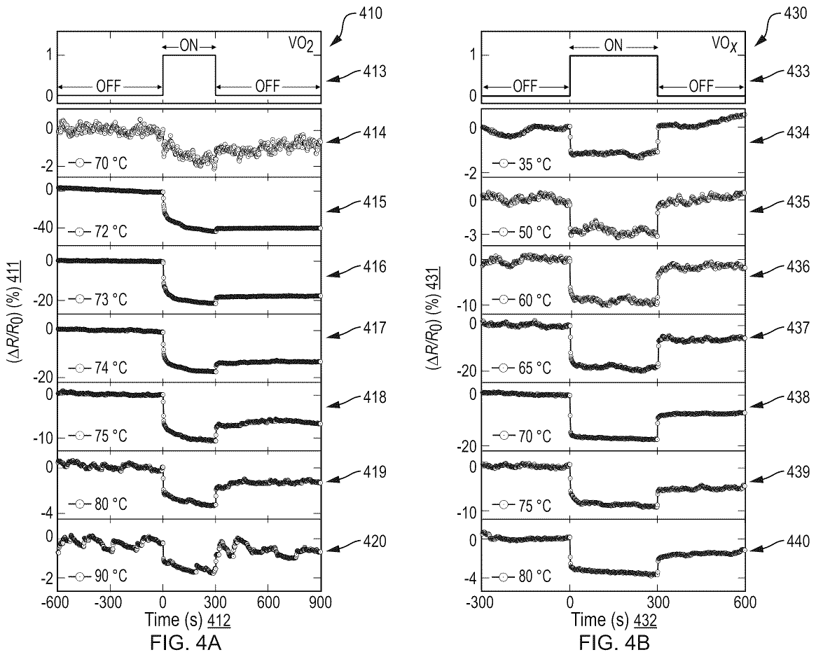

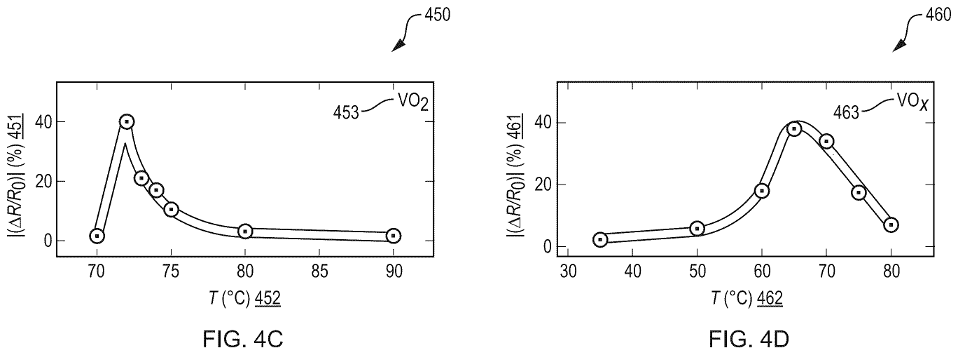

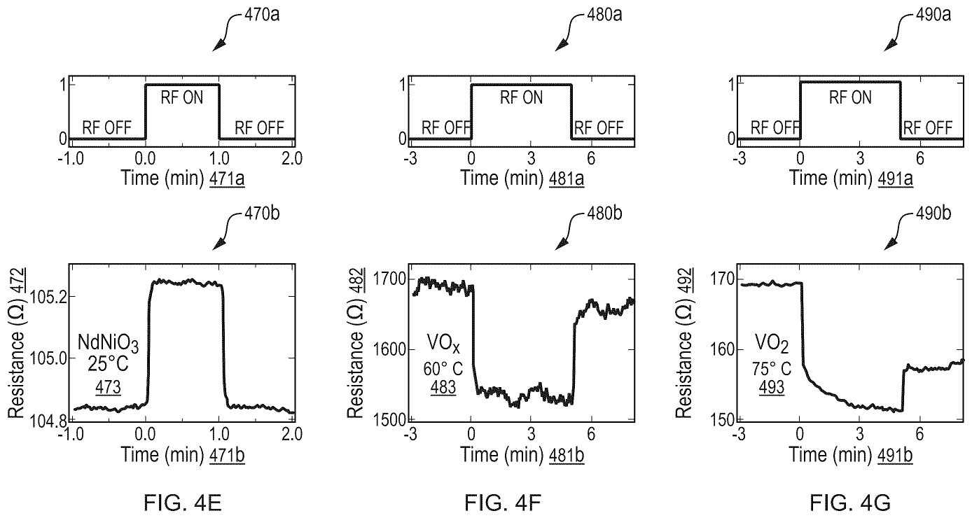

FIGS. 4A and 4B show plots 410 and 430 respectively, each containing respective sub-plots (414-420 FIG. 4A and 434-440 FIG. 4B), illustrating the RPCR 411 (FIG. 4A) and 431 (FIG. 4B) under irradiation of an RF signal versus time 412 (FIG. 4A) and 432 (FIG. 4B). In both plots 410 and 430, a RF signal of 2.4 GHz is measured with 100 gain for 300 seconds (5 minutes) at 8 cm distance.

Subplot 413 of FIG. 4A schematically illustrates the “On” and “Off” state for the RF signal during the duration of the experiment. It can be seen from subplot 413 that the signal is turned on at time 0 and turned off after 300 seconds. FIG. 4A also contains subplots 414-420 illustrating the RPCR 411 under irradiation from an RF signal versus time 412 in seconds. Plots 414-420 illustrate the difference in measured percentage change in resistance 411 over a range of VO₂ quantum material film temperatures. Namely, plot 414 illustrates the measured percentage change in resistance at 70° C., plot 415 at 72° C., plot 416 at 73° C., plot 417 at 74° C., plot 418 at 75° C., plot 419 at 80° C., and plot 420 at 90° C.

Subplot 433 of FIG. 4B schematically illustrates the “On” and “Off” state for the RF signal during the duration of the experiment. It can be seen from subplot 433 that the signal is turned on at time 0 and turned off after 300 seconds. FIG. 4B also contains subplots 434-440 illustrating the RPCR 431 under irradiation from an RF signal versus time 432 in seconds. Plots 434-440 illustrate the difference in measured percentage change in resistance over a range of VOₓ quantum material film temperatures. Specifically, plot 434 illustrates the measured percentage change in resistance at 35° C., plot 435 at 50° C., plot 436 at 60° C., plot 437 at 65° C., plot 438 at 70° C., plot 439 at 75° C., and plot 440 at 80° C.

After probing the structural and electronic properties of the stoichiometric and off-stoichiometric samples, the impact of RF wave exposure on these films was explored. The plots 413 and 433 of FIGS. 4A and 4B, respectively, show the ON:OFF state of the RF signal. The samples were heated to the desired temperature for each measurement. Once the temperature stabilized, the system was driven out of equilibrium by concentrating a 2.4-GHz RF wave with 100 gain from a distance of 8 cm onto the samples for 5 minutes during the “ON” state. Following each set of sensing measurements at a specific temperature, the films were ramped to 100° C. to remove any persistent conductivity or history effects. Subsequently, the samples were cooled down to room temperature and then heated to the desired temperature for the next measurement. The remaining plots 414-420 and 434-440 of FIGS. 4A and 4B, respectively show the relative percentage change in resistance (RPCR) 411 and 431, calculated using the formula ((R−R₀)/R₀)×100 (where R₀ is the initial resistance when the RF signal was turned off, and ΔR =R−R₀) as a function of time at different temperatures of the VO₂ and VOₓ samples, respectively.

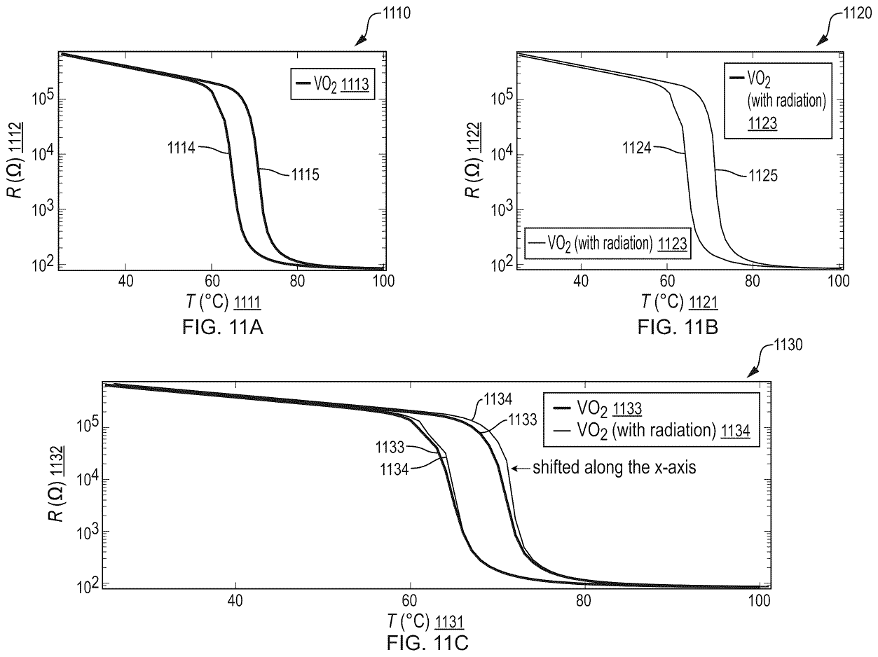

Firstly, FIGS. 4A and 4B show a drop in resistance as soon as the RF signal is activated (time=0), making the material more conducting. It is worth noting that the RF wave with a frequency of 2.4 GHz corresponds to an energy of 9.93 μeV, which is not sufficient for the excitation of electrons from the valence band to the conduction band, as the band gap of VO₂ is around 0.7 eV [26]. Therefore, this decrease in resistance induced by the RF wave may be due to the selective excitation of trapped electrons to the conduction band. Prior studies have demonstrated an IMT phase transition in VO₂ coplanar waveguides induced by intense high-frequency radiation [30, 31]. The decrease in resistance caused by RF waves may also occur due to alternative mechanisms, such as influencing the formation of conductive filaments within the VO₂ film [9, 10, 32, 33] or through the liberation of Poole-Frenkel electrons, where the electric field reduces the potential barrier, leading to a slight elevation in the carrier density [30, 34]. Moreover, the reduction in the RPCR due to the influence of RF waves can be anticipated through a straightforward application of the Joule heating mechanism [30, 35]. In this latter scenario, RF waves locally heat the film, causing a small temperature rise and subsequently making the sample more conductive. However, the resistance versus temperature of the VO₂ film with the RF radiation was measured both on and off (See FIGS. 11A-11C discussed below. See also [19]). The two curves cannot be overlapped by simply shifting them along the temperature axis. Further, the change in temperature due to RF radiation is estimated at different temperatures from the resistance versus temperature curve (See FIG. 3D) and RPCR (See FIG. 4A) of the VO₂ film. These observations suggest a nonthermal effect associated with the RF radiation on the VO₂ film.

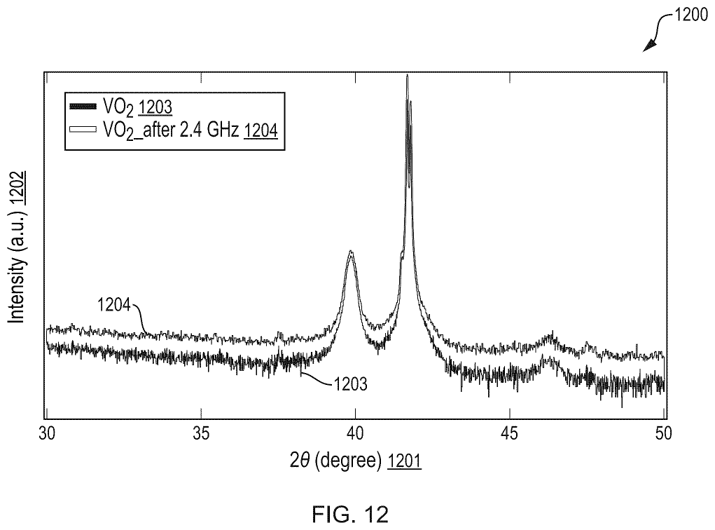

Secondly, there is a sharp increase in the resistance of the VO₂ film immediately after the RF signal is turned off (time=300s), which again suggests a different mechanism potentially distinct from only Joule heating, as the resistance typically recovers gradually in the case of heat dissipation [36,37]. To check whether this resistance change with the RF signal is related to the material's structure, X-ray diffraction measurements were conducted after shining 2.4-GHz RF waves on a VO₂ sample for 5 minutes. However, there was no observable change in the film peak (See FIG. 12 discussed below. See also [19]).

Thirdly, when the samples were in either the insulating or metallic state, the resistance recovered back to the original resistance (R₀), whereas the resistance did not fully recover to the original value after removing the RF signal when the samples were in the hysteresis region. This behavior can be well explained by the hysteresis effect, where the resistance does not return to its initial value if the temperature is ramped up (i.e., the resistance does not decrease) and down (i.e., the resistance does not increase) only within the hysteresis region [38, 39]. The abrupt change of channel resistance with RF waves at different temperatures is fascinating, as this can be exploited as a design parameter in sensing. Further, by tuning the oxygen ratio, the hysteresis region formed by IMT can be tuned, as well as the IMT transition temperature.

FIGS. 4C and 4D show plots 450 and 460, respectively, illustrating temporal evolution of the maximum RPCR of the VO₂ and VOₓ films, respectively. Plot 450 of FIG. 4C shows temporal evolution of the maximum RPCR 451 of the VO₂ 453 over time 452. Plot 460 of FIG. 4D shows temporal evolution of the maximum RPCR 461 of the VOₓ 463 over time 462.

FIGS. 4C and 4D illustrate the RPCR as a function of measured temperatures for the VO₂ and VOₓ samples, respectively. Interestingly, the maxima of the curves are intriguingly close to the

$${T}_{IMT}^{h} ,$$

which suggests maximum changes in resistance approaching the percolation threshold [40-42]. In the future, in operando microscopy techniques such as scanning microwave impedance microscopy and scanning near-field infrared microscopy coupled with RF exposure could enable a comprehensive understanding of the microscopic mechanisms involved and could form the subject of further studies.

FIGS. 4E-4G show plots 470a-b, 480a-b, and 490a-b, respectively, which illustrate the change in resistance (472, 482, 492) with the application of RF radiation at different temperatures for thin films of NdNiO3 (at 25° C.) 473, VOₓ (at 60° C.) 483, and VO₂ (at 75° C.) 493. The plots 470a, 480a, and 490a show the time 471a, 481a, and 491a of RF ON and OFF whereas the plots 470b, 480b, and 490b show the corresponding change in resistance 472, 482, and 492, respectively, with RF radiation over time 471b, 481b, and 491b. The resistance 472, 482, and 492 increases with RF radiation for NdNiO3 473 and decreases for VO₂ 493 and VOₓ 483 thin films.

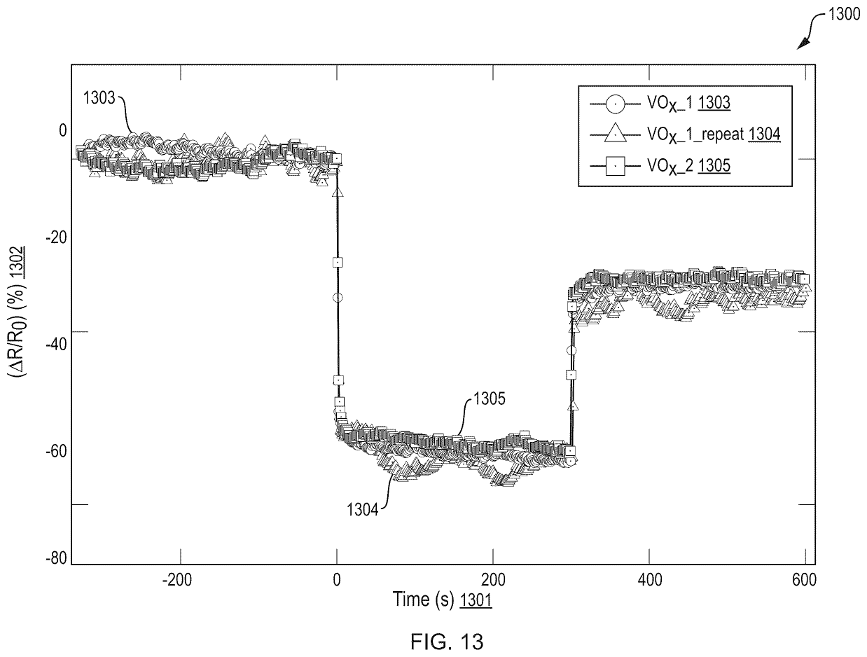

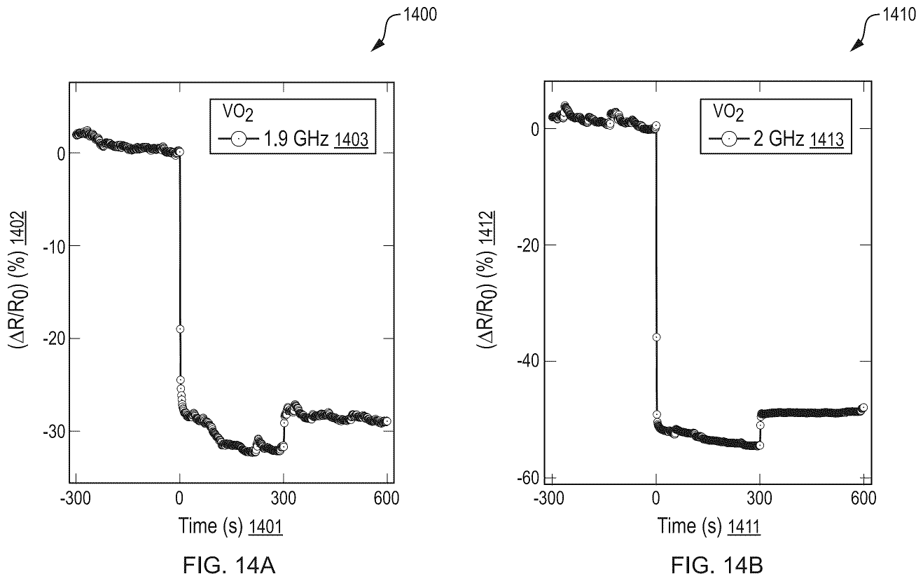

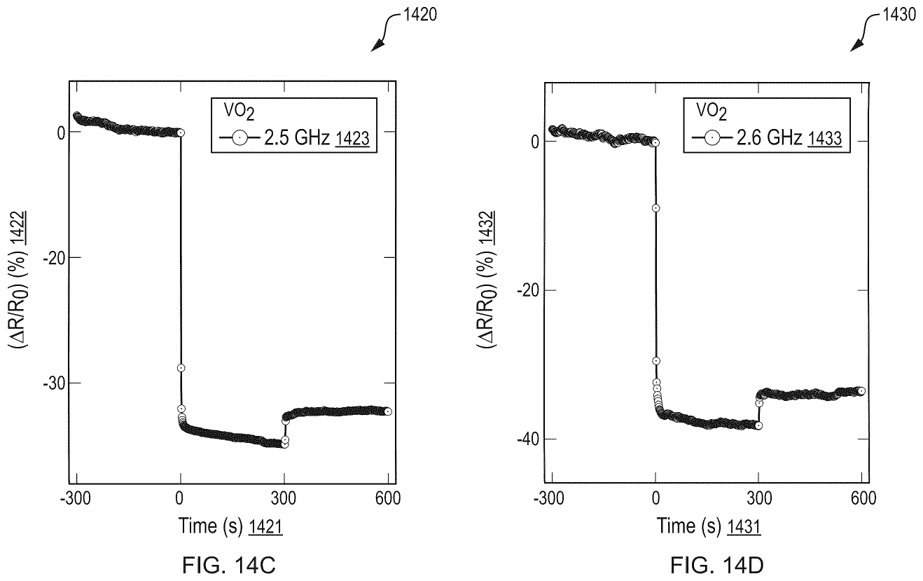

To check the reproducibility of embodiments, a 2.4-GHz RF wave with 100 gain was concentrated on a VOₓ sample for 5 minutes from a distance of 8 cm at 73° C. This procedure was then repeated for the same sample and also for a different sample (See FIG. 13 discussed below. See also [19]). The RPCR values for all these cases are found to be almost identical. Additionally, the influence of RF waves on the sample was explored using frequencies other than the technologically important 2.4 GHz used in wireless communications, such as Wi-Fi and cellular applications. Similar conductance modulation effects on the VO₂ film (See FIGS. 14A-14D, discussed below. See also [19]) was observed, suggesting that the conductance modulation phenomenon is not exclusive to specific frequencies but holds true across a range of RF waves. This versatility in responsiveness to diverse frequencies positions VO₂ as a potential candidate for applications in the evolving landscape of communication technologies.

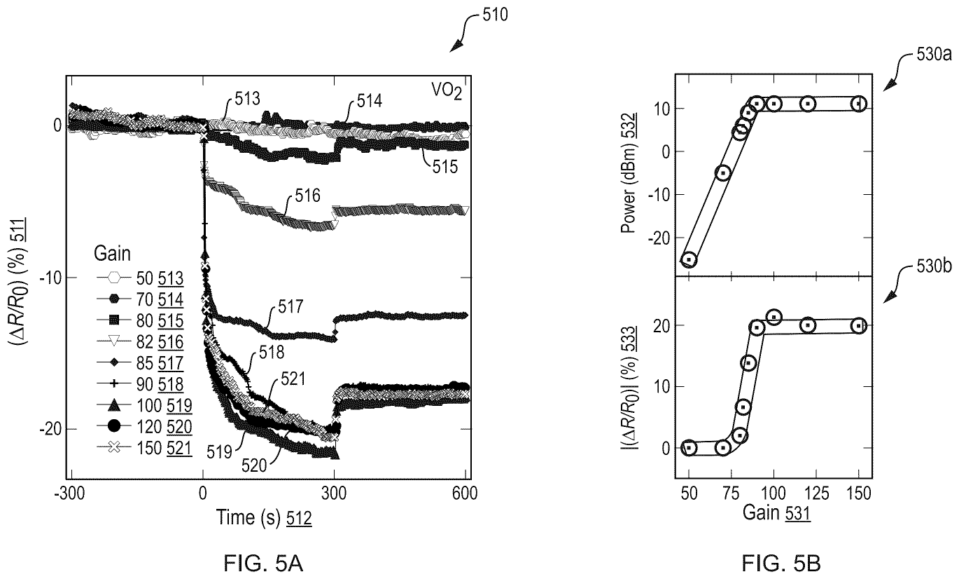

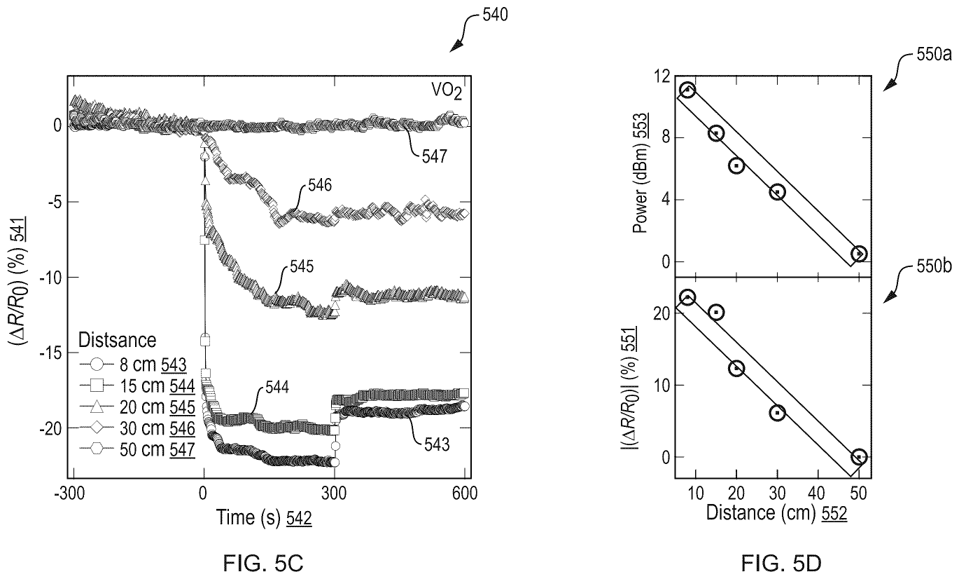

After establishing the effect of RF waves on VO₂ and VOₓ samples at different temperatures, the effect of RF signal strength was explored by varying the power. The results from the exploration of varying power are shown in FIGS. 5A-D. FIG. 5A is a plot 510 illustrating the RPCR 511 of the VO₂ quantum material film while subject to RF signals with different gain values versus time 512. Specifically, the plot 510 shows the RPCR 511 while the VO₂ quantum material film is subjected to a signal with a gain of 50 513, a gain of 70 514, a gain of 80 515, a gain of 82 516, a gain of 85 517, a gain of 90 518, a gain of 100 519, a gain of 120 520, and a gain of 150 521. FIG. 5B shows plots 530a and 530b of power received 532 (plot 530a) and the maximum RPCR 533 (plot 530b) versus gain 531.

FIG. 5C is a plot 540 illustrating the RPCR of the VO₂ quantum material film under an RF signal from different distances versus time 542. Specifically, the plot 540 shows the RPCR 541 while the VO₂ quantum material film is subjected to a signal from a distance of 8 cm 543, 15 cm 544, 20 cm 545, 30 cm 546, and 50 cm 547. FIG. 5D shows plots 550a and 550b power received 553 (plots 550a) and the maximum RPCR 551 (plot 550b) versus distance 552 from the RF antenna. Both the power 553 and the RPCR 551 can be seen decreasing as the distance 552 increases.

FIG. 5A shows the RPCR 511 of the VO₂ sample as a function of time 512 when radiated with a 2.4-GHz RF signal (for 5 minutes at a distance of 8 cm) at 73° C. with different gain values 513-521. The power received 532 at the sample surface corresponding to the gain 531 and the maximum RPCR 533 with gain 531 is shown in FIG. 5B. Notably, the maximum RPCR remains minimal at lower gains (50 and 60), increases progressively with higher gain values, and stabilizes when the gain exceeds 80. It is worth noting that the RPCR is directly proportional to the power received by the sample at a constant temperature. Furthermore, FIG. 5C shows the RPCR 541 as a function of time 542, while the RF wave was concentrated on the VO₂ film from different distances 543-547 between the RF antenna and the sample. As can be seen from the graph 540, the RPCR 541 decreases with increasing distance between the RF source and the sample. This can be understood by considering the decrease of power with increasing distance. To validate this, the power 553 was measured at the corresponding distances 552 and found that the power 553 indeed decreases as the distance 552 increases (See FIG. 5D). Therefore, the observed changes in RPCR concerning gain and distance can be attributed to the power received by the sample.

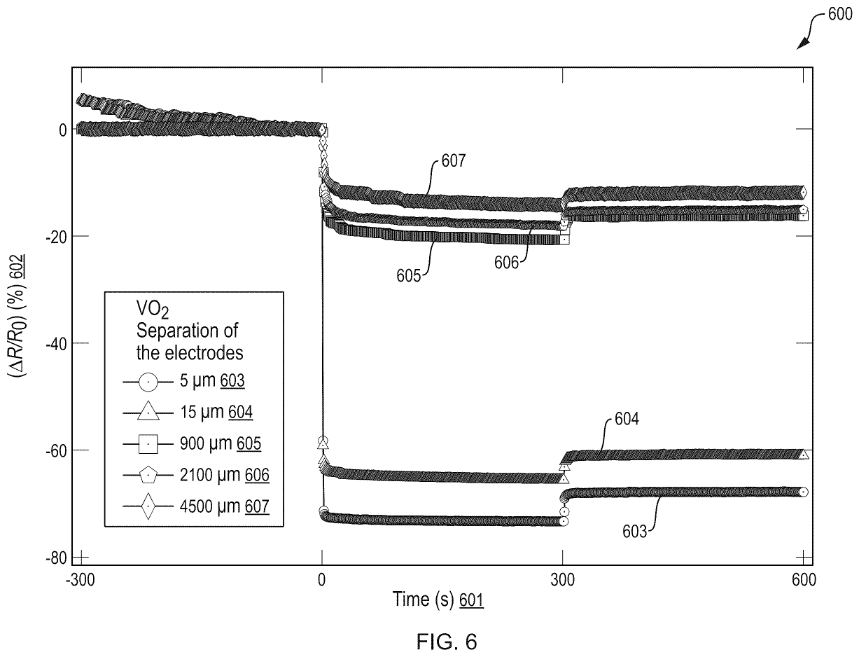

The effect of RF waves on sensor channel dimensions was examined by varying the spacing between the metal electrodes on the VO₂ sample and the results of this examination are shown in FIG. 6. FIG. 6 is a plot 600 illustrating the RPCR 602 of VO₂ quantum material films with different separations of electrodes while exposed to a 2.4 GHz signal with a gain of 100 at 73° C. for five minutes (time 601) at a distance of 8 cm. Specifically, plot 600 illustrates the percentage change in resistance 602 over time 601 for electrode spacings of 5 μm 603, 15 μm 604, 900 μm 605, 2100 μm 606, and 4500 μm 607. FIG. 6 shows that an increase in the distance 603-607 between the electrodes results in a decrease in the RPCR 602 when a 2.4-GHz RF wave with a gain value of 100 from a distance of 8 cm was turned on at a sample temperature of 73° C. The measurements were done using a probing voltage of ±0.05 V, which may be high enough to induce conducting filament formation in VO₂ devices, especially when the temperature is close to the phase transition [32, 43].

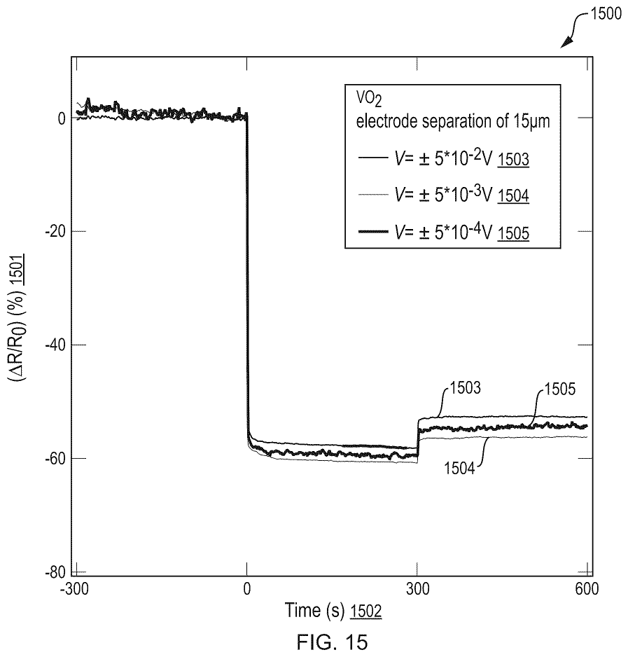

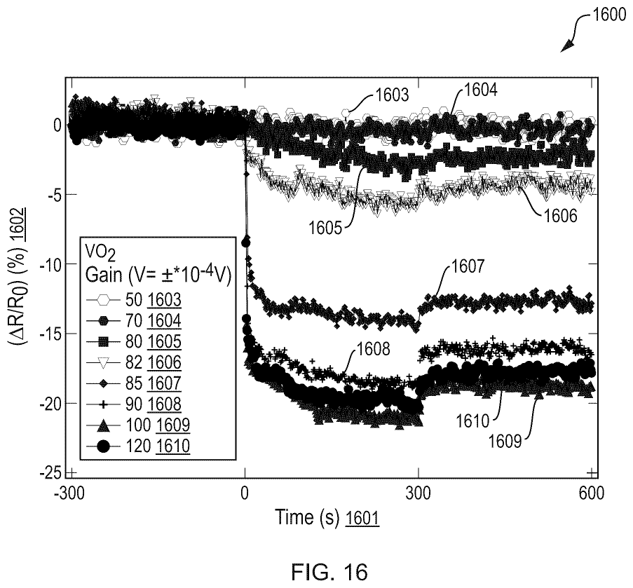

Therefore, the RPCR of the 15-μm VO₂ device was also measured at 73° C. using smaller voltages (±0.005 and ±0.0005 V) under a 2.4-GHz RF radiation with a gain of 100 from a distance of 8 cm (See FIG. 15 discussed below. See also [19]). Also, the RPCR measurement of the VO₂ film was repeated with different gain values that has been measured before (See FIG. 5A) by using a smaller voltage of 0.0005 V (See FIG. 16 discussed below. See also [19]). A similar value of RPCR obtained by applying smaller voltages suggests that the change in RPCR of the VO₂ film is due to the RF radiation and not because of the higher probed current and/or voltages. Further, a VO₂ film with much smaller electrode separations was used to enhance the RPCR. The RPCR values were found to be ˜73% and 65%, when the electrode separations were 5 and 15 m, respectively. The values of peak RPCR as a function of electrode separation are shown in Table II below. The enhancement in sensitivity by reducing the channel separation points results in the ability of embodiments to be optimized for particular applications.

TABLE II
Peak RPCR as a Function of Electrode Separation

| | Electrode Separation (μm) | | | | | |
|---|---|---|---|---|---|---|
| | 5 | 15 | 300 | 900 | 2100 | 4500 |
| Peak RPCR | 73.29 | 65.48 | 21.23 | 20.55 | 17.74 | 13.93 |

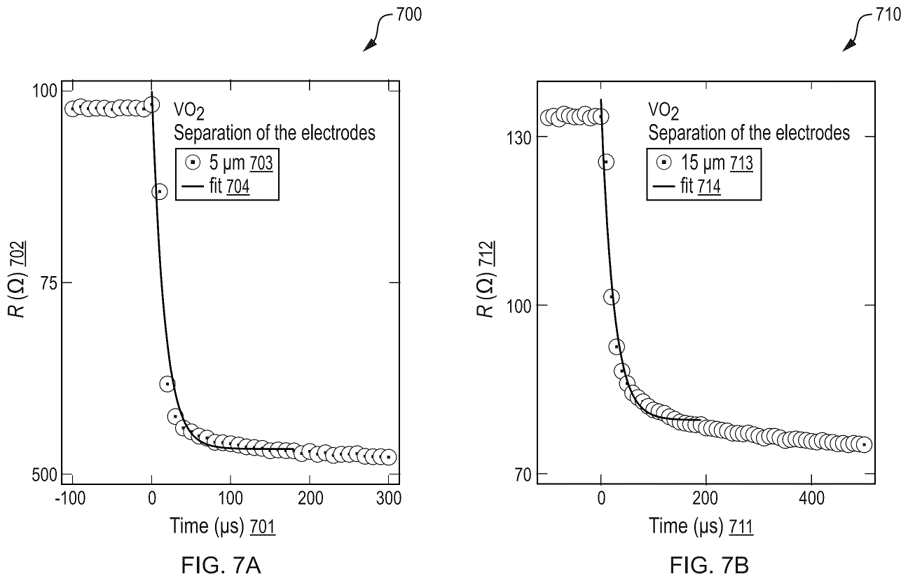

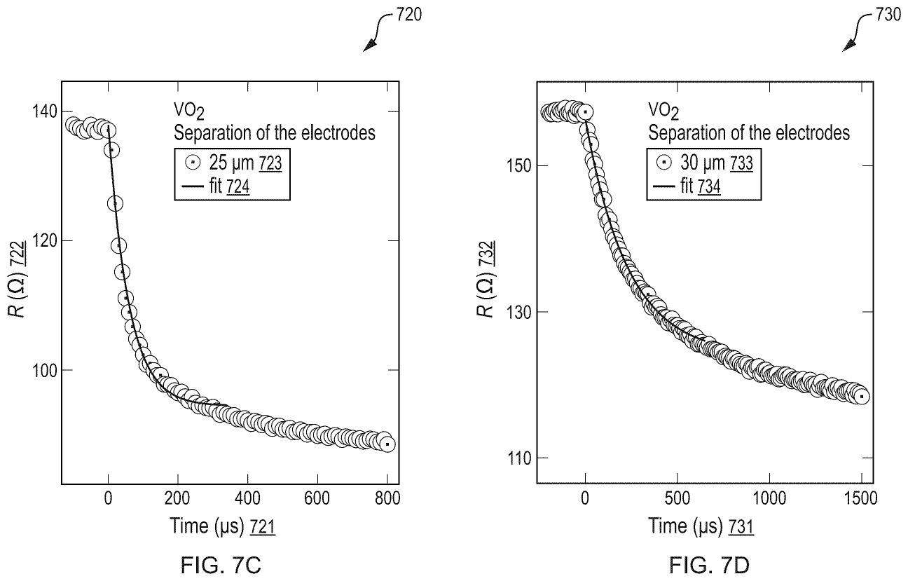

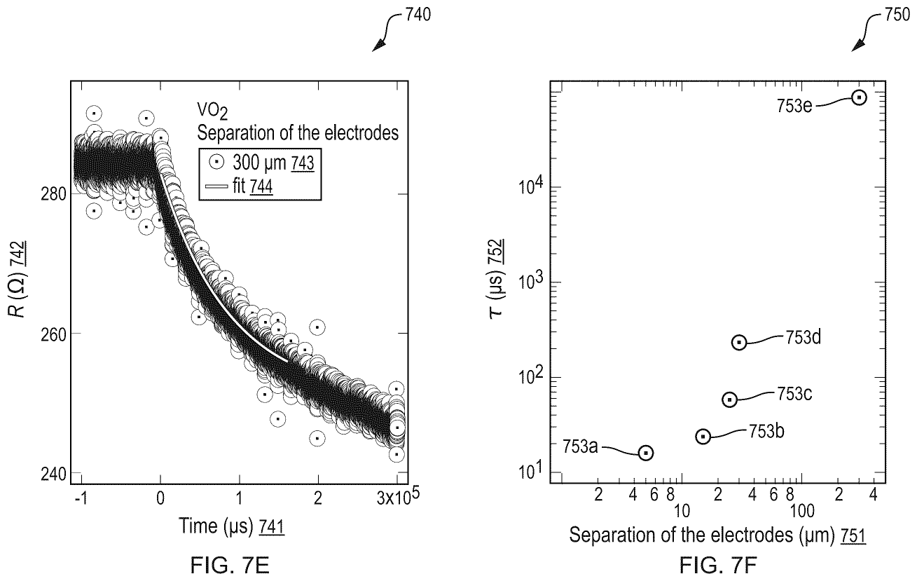

To elucidate the dynamics associated with the reduction in resistance induced by RF waves, time-resolved measurements were conducted, capturing resistance values at intervals of 10 μs. The results are shown in FIGS. 7A-7F. FIGS. 7A-7E show plots 700, 710, 720, 730, and 740 respectively, of resistance (702, 712, 722, 732, 742, respectively) of VO₂ quantum material films with different distances between electrodes as a function of time (701, 711, 721, 731, 741, respectively) while subjected to a 2.4 GHz RF signal with a gain of 100 at 73° C. at a distance of 8 cm. FIG. 7A shows plot 700 of resistance 702 as a function of time 701 with an electrode spacing 703 of 5 μm on the VO₂ quantum material film. The plot 700 also includes the resulting curve 704 from fitting the data 702 to the equation R=a+be^{-t/τ}, where a and b are constants, and r is the time constant. FIG. 7B shows plot 710 illustrating resistance 712 as a function of time 711 with an electrode spacing 713 of 15 μm on the VO₂ quantum material film. The plot 710 also includes the resulting curve 714 from fitting the data 712 to the equation R=a+be^{-t/τ}, where a and b are constants, and τ is the time constant. FIG. 7C shows plot 720 illustrating resistance 722 as a function of time 721 with an electrode spacing 723 of 25 μm on the VO₂ quantum material film. The plot 720 also includes the resulting curve 724 from fitting the data 722 to the equation R=a+be^{-t/τ}, where a and b are constants, and r is the time constant. FIG. 7D shows plot 730 illustrating resistance 732 as a function of time 731 with an electrode spacing 733 of 30 μm on the VO₂ quantum material film. The plot 730 also includes the resulting curve 734 from fitting the data 732 to the equation R=a+be^{-t/τ}, where a and b are constants, and r is the time constant. FIG. 7E shows plot 740 illustrating resistance 742 as a function of time 741 with an electrode spacing 743 of 300 μm on the VO₂ quantum material film. The plot 740 also includes the resulting curve 744 from fitting the data 742 to the equation R=a+be^{-t/τ}, where a and b are constants, and τ is the time constant. FIG. 7F is a plot 750 illustrating the time constant 752 plotted 753a-e as a function of the separation of the electrodes 751 on the VO₂ quantum material film.

FIGS. 7A-7E show the temporal evolution of resistance drop upon the activation of RF waves, focusing on various channel separations within the VO₂ film (See FIGS. 16A-16D discussed below for the evolution of resistance for a longer time scale, See also [19]). It is noteworthy to highlight that the response time scales varies with channel dimensions. The drop in resistance exhibits a distinct profile, characterized by a sharp and rapid reduction in the case of shorter channels, transitioning to a more gradual descent as the channel separation is increased.

To understand the time constant related to the drop of the resistance with RF wave, the resistance (R) versus time (t) curve was fitted (immediately following the RF exposure) with the equation R=a+be^{-t/τ}, where a and b are constants, and r is the time constant (black curves 704, 714, 724, 734, and 744 in FIGS. 7A-7E). The time constant increases with the increase of the channel separation of the VO₂ film (See FIG. 7F). This insight points towards the intricate interplay between channel dimensions and the manifestation of RF induced effects, particularly in the context of conducting filament formation within the VO₂ film that has previously been ascribed as a possible mechanism for reduction in resistance of vanadium oxide films exposed to terahertz fields [9,10]. The high-speed response could potentially be enhanced further by reducing channel separation through the application of advanced techniques such as e-beam lithography or other similar methods.

### Plurality of RF Sensing Devices

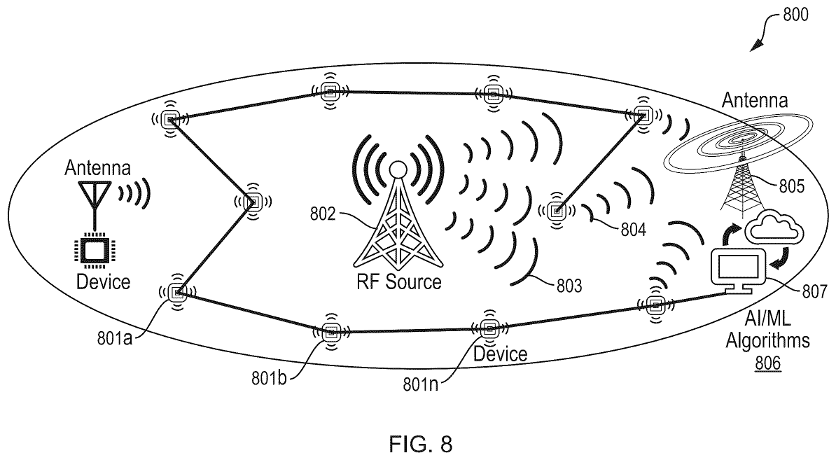

Embodiments can employ a plurality of RF sensing devices, as described herein, in an environment to sense RF signals in the environment. FIG. 8 is a schematic illustrating such an example deployment 800. In the deployment 800, a plurality of RF sensing devices 801a-n are dispersed. This configuration utilizes a plurality of RF sensing devices 801a-n arranged in an array like pattern over a desired operating environment. A RF signal source 802 may propagate a RF signal 803 throughout the environment, and the signal 803 may then be received by one or more of the RF sensing devices 801a-n. The RF sensing devices 801a-n may include source meters that measure and output resistance of a quantum film while exposed to the signal 803. The measured resistance data may be transmitted to a controlled antenna 805 which, in turn, transmits the data to one or more computing devices 807. This transmission may be done over the air or transmitted over wire. The one or more computing devices 807 may store the data using any computer storage known to those of skill in the art. Further, the computing device 807 may analyze the data using, e.g., artificial intelligence (AI)/machine learning (ML) 806 functionality, to determine properties of the RF signal 803. Further, there may be multiple RF signals in the environment and properties of the multiple signals may be determined by the computing device 807. The deployment 800 uses resistance-based RF sensors and machine learning algorithms to efficiently collect and processes data. The deployment 800 has enhanced spectrum awareness and protects receivers from interference in complex environments.

### Example Experimental Setup and Results

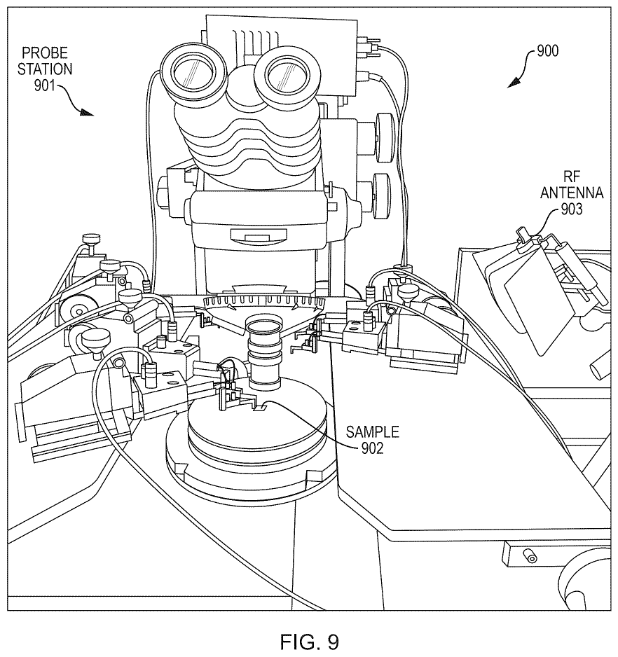

FIGS. 9-10 and the accompanying descriptions below illustrate example t experimental test set-ups. Further, FIGS. 11A-C, 12, 13, 14A-D, 15, 16, and 17A-E and the accompanying descriptions illustrate example experiment results for embodiments disclosed herein.

FIG. 9 shows an experimental setup 900 of RF waves concentrating onto a device 902 placed on a probe station 901. The sample quantum material film device 902 is placed near the RF antenna 903.

FIG. 10 shows a calibration setup 1000 used to measure the received power (at the RF receiver 1003) of the RF wave from the RF antenna 1001, using a spectrum analyzer 1002 in the COSMOS testbed environment.

FIGS. 11A-11C illustrate resistance sensing of the VO₂ quantum material film as a function of temperature with and without being exposed to RF radiation. FIG. 11A is a plot 1100 illustrating resistance 1112 for the VO₂ quantum material film 1113 as a function of temperature 1111 (during heating the sample from 25° C. to 100° C. 1115 and cooling the sample from 100° C. to 25° C. 1114) without being exposed to RF radiation. FIG. 11B is a plot 1120 illustrating the resistance 1122 of the VO₂ quantum material film 1123 while exposed to RF radiation as a function of temperature 1121 (during heating the sample from 25° C. to 100° C. 1125 and cooling the sample from 100° C. to 25° C. 1124). FIG. 11C is a plot 1130 illustrating a comparison between plots 1110 and 1120 of FIGS. 11A and 111B, respectively. Plot 1130 shows the resistance 1132 of the VO₂ quantum material film as a function of temperature 1131 when the film is not exposed to RF radiation 1133 and when the film is exposed to RF radiation 1134. As can be seen in plot 1130 of FIG. 11C, the non-overlapping nature of the lines points toward the non-thermal effects of RF radiation on VO₂ quantum material film.

FIG. 12 is a plot 1200 illustrating X-ray diffraction (XRD) scan data of the VO₂ quantum material film before and after exposure to radiation of an RF signal of 2.4 GHz for 5 minutes. Plot 1200 shows the intensity (arbitrary unit) 1202 versus 2θ (degree) 1201 for the VO₂ quantum material film before 1203 and after 1204 introduction of a 2.4 GHz RF signal. In order to investigate if the modulation of resistance due to the RF signal is associated with the material's structure, XRD assessments were performed subsequent to exposing a VO₂ quantum material film sample to the RF waves. No discernible change in the film's peak position or shape is observed.

FIG. 13 is a plot 1300 illustrating RPCR (RPCR) 1302 of two VOₓ quantum material films 1303 and 1305 while subjected to a 2.4 GHz RF signal with 100 gain for 5 minutes at 8 cm and at 73° C. versus time 1301. In order to check the reproducibility of the RF effect on the sample, the RPCR was measured for a VOₓ sample 1303 twice 1304 and repeated for another VOₓ sample 1305. The plot 1300 shows that similar RPCRs were measured for all these cases (1303, 1304, and 1305) in experiments conducted over a timeframe of several weeks.

FIGS. 14A-14D are plots 1400, 1410, 1420, and 1430, respectively, of RPCR (1402, 1412, 1422, and 1432, respectively) of the VO₂ quantum material film while exposed to an RF signals with different frequencies and a 100 gain for 5 minutes at 8 cm and at 73° C. versus time (1401, 1411, 1421, and 1431, respectively). FIG. 14A shows plot 1400 illustrating RPCR 1402 for a VO₂ quantum material film exposed to a 1.9 GHz frequency over time 1401. FIG. 14B shows plot 1410 illustrating RPCR 1412 for a VO₂ quantum material film exposed to a 2.0 GHz frequency over time 1411. FIG. 14C shows plot 1420 illustrating RPCR 1422 for a VO₂ quantum material film exposed to a 2.5 GHz frequency over time 1421. FIG. 14D shows plot 1430 illustrating RPCR 1432 for a VO₂ quantum material film exposed to a 2.6 GHz frequency over time 1431.

FIG. 15 shows plot 1500 illustrating the RPCR 1501 of a VO₂ quantum material film (with 15 μm electrode separation) at 73° C. over time 1502 using different voltages to measure the resistance of the quantum material film while the film is under a 2.4 GHz RF radiation with a gain value of 100 from a distance of 8 cm. Plot 1500 shows the RPCR 1501 data collected subject to voltages ±5 ×10⁻² V 1503, ±5×10⁻³ V 1504, and ±5×10⁻⁴ V 1505. A similar RPCR 1501 using different voltages, as can be seen in the plot 1500, suggests the change in RPCR of the VO₂ quantum material film is due to RF radiation, and not because of the higher probed currents or voltages used to measure the resistance.

FIG. 16 shows plot 1600 illustrating RPCR 1602 of the VO₂ quantum material film versus time 1601 while the file is under RF radiation (2.4 GHz at 73° C. for 5 minutes from a distance of 8 cm) with an applied voltage of 0.0005 V at different gain values. Specifically, plot 1600 RPCR 1602 data while the film is subject to RF signals with a gain of 50 1603, a gain of 70 1604, a gain of 80 1605, a gain of 82 1606, a gain of 85 1607, a gain of 90 1608, a gain of 100 1609, and a gain of 120 1610. The RPCR trend is similar for both cases, particularly using a higher voltage (±0.05 V as seen in FIG. 5A) and a lower voltage (±0.0005 V as seen in FIG. 16). This confirms that the change in resistance is not simply due to a high probing voltage or current.

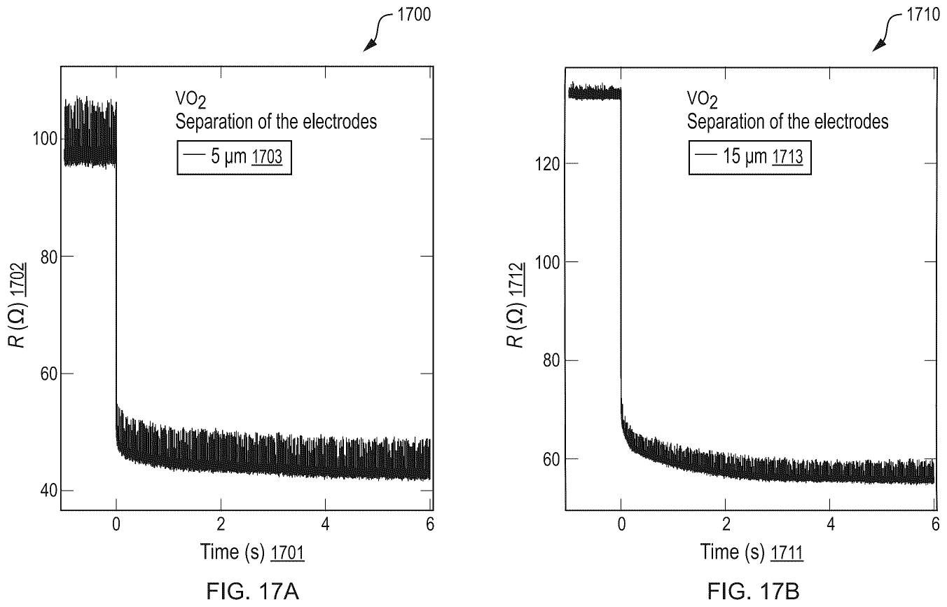

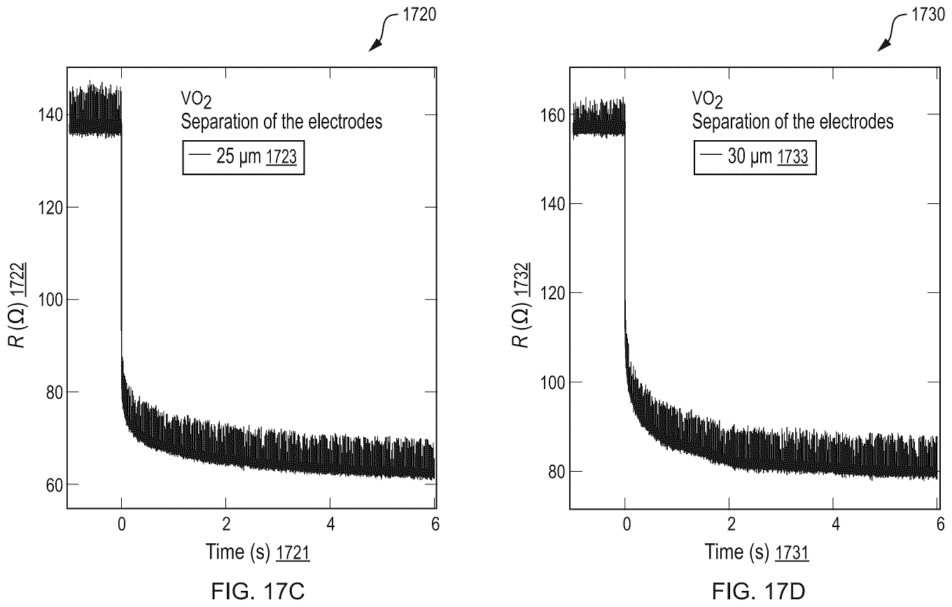

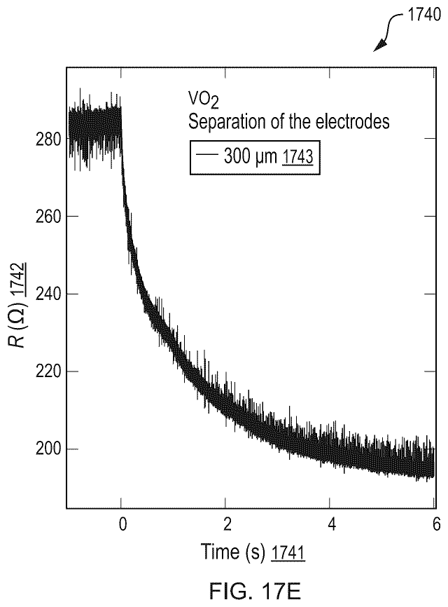

FIGS. 17A-17E show plots 1700, 1710, 1720, 1730, and 1740, respectively, illustrating resistance (1702, 1717, 1722, 1732, and 1742, respectively) measured from VO₂ quantum material film devices with different channel gaps as a function of time (1701, 1711, 1721, 1731, and 1741, respectively) while the films are exposed to a 2.4 GHz RF signal at 73° C. for 5 minutes from a distance of 8 cm. Plot 1700 shows the resistance 1702 for a VO₂ quantum material film with an electrode separation 1703 of 5 μm over time 1701. Plot 1710 shows the resistance 1712 for a VO₂ quantum material film with an electrode separation 1713 of 15 μm over time 1711. Plot 1720 illustrates the resistance 1722, over time 1721, for a VO₂ quantum material film with an electrode separation 1723 of 25 μm. Plot 1730 shows the resistance 1732, over time 1731, for a VO₂ quantum material film with an electrode separation 1733 of 30 μm. Plot 1740 shows the resistance 1742, over time 1741, for a VO₂ quantum material film with an electrode separation 1743 of 300 μm. FIGS. 17A-17E show that the drop of resistance is sharper for the shorter channel and becomes gradual with the increase in channel separation.

### CONCLUSIONS

The resistance (R) value in ohms at different temperatures (T) from FIG. 3D discussed above has been identified for the VO₂ quantum material film. From the (ΔR/R₀)% (See FIGS. 4A-4D discussed above), the change in resistance (ΔR) with radiation at different temperatures has been estimated. Finally, the necessary temperature change (ΔT) to obtain this ΔR has been noted from the resistance versus temperature plots of FIGS. 4C and 4D. It was found that the ΔT is not the same at all temperatures (See Table III below). This points toward a possible contribution of RF-induced mechanisms, rather than a pure thermal effect.

TABLE III
Estimation of Temperature Change with RF Radiation at Different
Temperatures for the VO₂ Quantum Material Film

| T (° C.) | R (T) (Ohms) | (ΔR/R₀) % | ΔR (Ohms) | ΔT (° C.) |
|---|---|---|---|---|
| 70 | 18649.4 | −1.924 | 358.81 | 0.02 |
| 73 | 381.614 | −21.225 | 81 | 0.44 |
| 80 | 113.244 | −3.2 | 3.62 | 0.64 |
| 90 | 89.592 | −1.7 | 1.52 | 2.96 |

VO₂ and off-stoichiometric VOₓ films were grown on c-Al₂O₃ substrates and their structural and electrical properties were studied using XRD, RBS, and transport measurements. Further, the effect of 2.4-GHz radiation on these samples was investigated by varying the temperature, frequency, gain, distance, power, and sample size. Interestingly, the application of the RF wave makes the samples more conducting and opens up avenues for applications as RF sensors. The RPCR scales with decreasing channel separation, reaching a value of ˜73% for the 5-μm channel gap. It was found that the samples are most sensitive proximal to the transition boundary, and this offers a path to devices that can respond at various temperatures by varying crystal stoichiometry and doping. The time-resolved RF measurements suggest the rapid response of the film on microsecond time scales upon the incidence of RF waves. Furthermore, the influence of RF waves is detectable across a broad spectrum of microwave frequencies, offering potential applications in future communications technologies.

### Computer Support

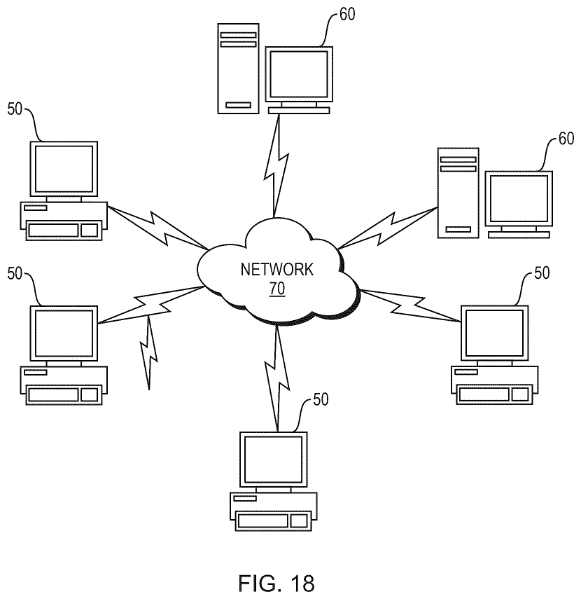

FIG. 18 is a schematic view of a computer network in which embodiments or functionality of embodiments, e.g., the data analyzing described herein, may be implemented.

Client computer(s)/devices 50 and server computer(s) 60 provide processing, storage, and input/output (I/O) devices executing application programs and the like. Client computer(s)/device(s) 50 can also be linked through communications network 70 to other computing devices, including other client device(s)/processor(s) 50 and server computer(s) 60. Communications network 70 can be part of a remote access network, a global network (e.g., the Internet), cloud computing servers or service, a worldwide collection of computers, local area or wide area networks, and gateways that currently use respective protocols (e.g., TCP/IP, Bluetooth®, etc.) to communicate with one another. Other electronic device/computer network architectures are suitable.

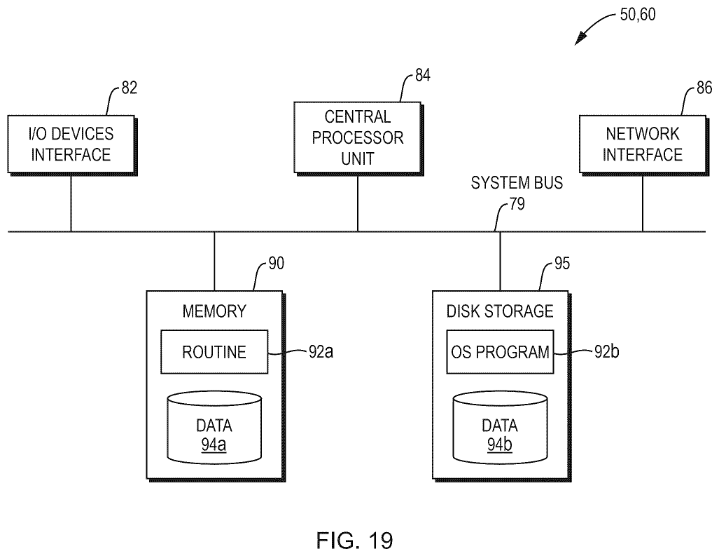

FIG. 19 is a block diagram illustrating an example embodiment of a computer node (e.g., client processor(s)/device(s) 50 or server computer(s) 60) in the computer network 70 of FIG. 18. Each computer node 50, 60 contains system bus 79, where a bus is a set of hardware lines used for data transfer among components of a computer or processing system. The system bus 79 is essentially a shared conduit that connects different elements of a computer system (e.g., processor, disk storage, memory, I/O ports, network ports, etc.) that enables transfer of information between the elements. Attached to the system bus 79 is an I/O device interface 82 for connecting various input and output devices (e.g., keyboard, mouse, display(s), printer(s), speaker(s), etc.) to the computer node 50, 60. A network interface 86 allows the computer node to connect to various other devices attached to a network (e.g., the network 70 of FIG. 18). A memory 90 provides volatile storage for computer software instructions 92a and data 94a used to implement an embodiment, or portion of an embodiment, of the present disclosure. A disk storage 95 provides non-volatile storage for the computer software instructions 92b and data 94b used to implement an embodiment of the present disclosure. A central processor unit 84 is also attached to the system bus 79 and provides for execution of computer instructions.

In one embodiment, the processor routines 92a-92b and data 94a-94b are a computer program product (generally referenced as 92), including a computer readable medium (e.g., a removable storage medium such as DVD-ROM(s), CD-ROM(s), diskette(s), tape(s), etc.) that provides at least a portion of the software instructions for an embodiment or portion thereof. Computer program product 92 can be installed by any suitable software installation procedure, as is well known in the art. In another embodiment, at least a portion of the software instructions may also be downloaded over a cable, communication, and/or wireless connection. In other embodiments, the disclosure programs are a computer program propagated signal product embodied on a propagated signal on a propagation medium (e.g., a radio wave, an infrared wave, a laser wave, a sound wave, or an electrical wave propagated over a global network such as the Internet, or other network(s)). Such carrier medium or signals provide at least a portion of the software instructions for the present disclosure routines/program 92.

In alternate embodiments, the propagated signal is an analog carrier wave or digital signal carried on the propagated medium. For example, the propagated signal may be a digitized signal propagated over a global network (e.g., the Internet), a telecommunications network, or other network (such as the network 70 of FIG. 18). In one embodiment, the propagated signal is a signal that is transmitted over the propagation medium over a period of time, such as the instructions for a software application sent in packets over a network over a period of milliseconds, seconds, minutes, or longer. In another embodiment, the computer readable medium of the computer program product 92 is a propagation medium that the computer system 50 may receive and read, such as by receiving the propagation medium and identifying a propagated signal embodied in the propagation medium, as described above for computer program propagated signal product.

Generally speaking, the term “carrier medium” or transient carrier encompasses the foregoing transient signals, propagated signals, propagated medium, storage medium, and the like.

In other embodiments, the program product 92 may be implemented as a so-called Software as a Service (SaaS), or other installation or communication supporting end-users.

Embodiments or aspects thereof may be implemented in the form of hardware including but not limited to hardware circuitry, firmware, or software. If implemented in software, the software may be stored on any non-transient computer readable medium that is configured to enable a processor to load the software or subsets of instructions thereof. The processor then executes the instructions and is configured to operate or cause an apparatus to operate in a manner as described herein.

Further, hardware, firmware, software, routines, or instructions may be described herein as performing certain actions and/or functions of the data processors. However, it should be appreciated that such descriptions contained herein are merely for convenience and that such actions in fact result from computing devices, processors, controllers, or other devices executing the firmware, software, routines, instructions, etc.

It should be understood that the flow diagrams, block diagrams, and network diagrams may include more or fewer elements, be arranged differently, or be represented differently. But it further should be understood that certain implementations may dictate the block and network diagrams and the number of block and network diagrams illustrating the execution of the embodiments be implemented in a particular way.

Accordingly, further embodiments may also be implemented in a variety of computer architectures, physical, virtual, cloud computers, and/or some combination thereof, and, thus, the data processors described herein are intended for purposes of illustration only and not as a limitation of the embodiments.

The teachings of all patents, applications, and references cited herein are incorporated by reference in their entirety.

While example embodiments have been particularly shown and described, it will be understood by those skilled in the art that various changes in form and details may be made therein without departing from the scope of the embodiments encompassed by the appended claims.

### REFERENCES

[1]I. F. Akyildiz, W.-Y. Lee, M. C. Vuran, and S. Mohanty, Next generation/dynamic spectrum access/cognitive radio wireless networks: A survey, Comput. Netw. 50, 2127 (2006).
[2]L. Lubna, H. Hameed, S. Ansari, A. Zahid, A. Sharif, H. T. Abbas, F. Algahtani, N. Mufti, S. Ullah, M. A. Imran, and Q. H. Abbasi, Radio frequency sensing and its innovative applications in diverse sectors: A comprehensive study, Front. Commun. Netw. 3, 1010228 (2022).
[3]D. K. Pin Tan, J. He, Y. Li, A. Bayesteh, Y. Chen, P. Zhu, andW. Tong, in 2021 1st IEEE International Online Symposium on Joint Communications & Sensing (IEEE, Dresden, Germany, 2021), p. 1.
[4]B.-G. Chae, H.-T. Kim, D.-H. Youn, and K.-Y. Kang, Abrupt metal-insulator transition observed in VO2 thin films induced by a switching voltage pulse, Phys. B: Condens. Matter 369, 76 (2005).
[5]D. E. Anagnostou, D. Torres, T. S. Teeslink, and N. Sepulveda, Vanadium dioxide for reconfigurable antennas and microwave devices: Enabling RF reconfigurability through smart materials, IEEE Antennas Propag. Mag. 62, 58 (2020).
[6]N. Ghazikhanian, J. del Valle, P. Salev, R. El Hage, Y. Kalcheim, C. Adda, and I. K. Schuller, Resistive switching localization by selective focused ion beam irradiation, Appl. Phys. Lett. 123, 123505 (2023).
[7]B.-J. Kim, Y. W. Lee, B.-G. Chae, S. J. Yun, S.-Y. Oh, H.-T. Kim, and Y.-S. Lim, Temperature dependence of the firstorder metal-insulator transition in VO2 and programmable critical temperature sensor, Appl. Phys. Lett. 90, 023515 (2007).
[8]E. Strelcov, Y. Lilach, and A. Kolmakov, Gas sensor based on metal-insulator transition in V02 nanowire thermistor, Nano Lett. 9, 2322 (2009).
[9]F. Qaderi, T. Rosca, M. Burla, J. Leuthold, D. Flandre, and A. M. Ionescu, Millimeter-wave to near-terahertz sensors based on reversible insulator-to-metal transition in VO2, Commun. Mater. 4, 34 (2023).
[10]F.Qaderi, Y. Horst, T. Blatter,M. Burla,D. Park, A. Gilani, J. Leuthold, and A. M. Ionescu, in 2022 47th International Conference on Infrared, Millimeter and Terahertz Waves (IRMMW-THz) (IEEE, Delft, Netherlands, 2022), p. 1.
[11]Z. Zhang, F. Zuo, C. Wan, A. Dutta, J. Kim, J. Rensberg, R. Nawrodt, H. H. Park, T. J. Larrabee, X. Guan, Y. Zhou, S. M. Prokes, C. Ronning, V. M. Shalaev, A. Boltasseva, M. A. Kats, and S. Ramanathan, Evolution of metallicity in vanadium dioxide by creation of oxygen vacancies, Phys. Rev. Appl. 7, 034008 (2017).
[12]J. Zhang, Z. Zhao, J. Li, H. Jin, F. Rehman, P. Chen, Y. Jiang, C. Chen, M. Cao, and Y. Zhao, Evolution of structural and electrical properties of oxygen-deficient VO2 under low temperature heating process, ACS Appl. Mater. Interfaces 9, 27135 (2017).
[13]J. G. Ramirez, T. Saerbeck, S. Wang, J. Trastoy, M. Malnou, J. Lesueur, J.-P. Crocombette, J. E. Villegas, and I. K. Schuller, Effect of disorder on the metal-insulator transition of vanadium oxides: Local versus global effects, Phys. Rev. B 91, 205123 (2015).
[14]B. Wang, J. Lai, E. Zhao, H. Hu, and S. Chen, Research on VOx uncooled infrared bolometer based on porous silicon, Front. Optoelectron. 5, 292 (2012).
[15]D. Wang, J. Bae, H.-J. Choi, S.-H. Baek, S. Woo, D. Park, and W. J. Choi, Modification of electrical properties of amorphous vanadium oxide (a-VOx) thin film thermistor for microbolometer, J. Alloys Compd. 937, 168295 (2023).
[16]B. Wang, N. Li, W.-F. Xie, J.-J. Lai, S.-Y. Wang, Y. Zheng, Z.-T. Chi, B. Yu, Y.-Q. Shen, and H.-L. Cong, Fabrication and characteristics of VOx microbolometer integrated into gold black absorbing layer, Ferroelectrics 579, 70 (2021).
[17]S. Deng, H. Yu, T. J. Park, A. N. Islam, S. Manna, A. Pofelski, Q. Wang, Y. Zhu, S. K. Sankaranarayanan, A. Sengupta, and S. Ramanathan, Selective area doping for Mott neuromorphic electronics, Sci. Adv. 9, eade4838 (2023).
[18]M. Mayer, Ion beam analysis of rough thin films, Nucl. Instrum. Methods Phys. Res. B Beam Interact. Mater. At. 194, 177 (2002).
[19] See the Supplemental Material http://link.aps.org/supplemental/10.1103/PhysRevApplied.22.014013 for the experimental setup in the laboratory, the calibration setup in the WINLAB, the effect of RF radiation on structural and transport properties, estimation of temperature change with RF radiation, reproducibility data, the effect of different RF frequencies on resistance, a similar RPCR using smaller voltages, and time-resolved measurements of the devices.
[20]D. Raychaudhuri, I. Seskar, G. Zussman, T. Korakis, D. Kilper, T. Chen, J. Kolodziejski, M. Sherman, Z. Kostic, X. Gu, H. Krishnaswamy, S. Maheshwari, P. Skrimponis, and C. Gutterman, in Proceedings of the 26th Annual International Conference on Mobile Computing and Networking, MobiCom '20 (Association for Computing Machinery, New York, NY, USA, 2020).
[21]Y. Cui and S. Ramanathan, Substrate effects on metalinsulator transition characteristics of rf-sputtered epitaxial VO2 thin films, J. Vac. Sci. Technol. A 29, 041502 (2011).
[22]Y. Zhou and S. Ramanathan, Heteroepitaxial VO2 thin films on GaN: Structure and metal-insulator transition characteristics, J. Appl. Phys. 112, 074114 (2012).
[23]G. Rampelberg, B. De Schutter, W. Devulder, K. Martens, I. Radu, and C. Detavernier, In situ X-ray diffraction study of the controlled oxidation and reduction in the V-O system for the synthesis of VO2 and V2O3 thin films, J. Mater. Chem. C 3, 11357 (2015).
[24]X. Ding, Y. Li, and Y. Zhang, Sol-gel derived tungsten doped VO2 thin films on Si substrate with tunable phase transition properties, Molecules 28, 3778 (2023).
[25]L. Feldman and J. Mayer, Fundamentals of Surface and Thin Film Analysis (Prentice Hall, 1986). https.//books.google.com/books?id=T8HMPAAACAAJ
[26]Z. Yang, S. Hart, C. Ko, A. Yacoby, and S. Ramanathan, Studies on electric triggering of the metal-insulator transition in VO2 thin films between 77 K and 300 K, J. Appl. Phys. 110, 033725 (2011).
[27]F. J.Wong, Y. Zhou, and S. Ramanathan, Epitaxial variants of VO2 thin films on complex oxide single crystal substrates with 3m surface symmetry, J. Cryst. Growth 364, 74 (2013).
[28]Y. Muraoka and Z. Hiroi,Metal-insulator transition of VO2 thin films grown on TiO2 (001) and (110) substrates, Appl. Phys. Lett. 80, 583 (2002).
[29]C. Chen, Y. Zhu, Y. Zhao, J. H. Lee, H.Wang, A. Bernussi, M. Holtz, and Z. Fan, VO2 multidomain heteroepitaxial growth and terahertz transmission modulation, Appl. Phys. Lett. 97, 211905 (2010).
[30]M. Liu, H. Y. Hwang, H. Tao, A. C. Strikwerda, K. Fan, G. R. Keiser, A. J. Sternbach, K. G. West, S. Kittiwatanakul, J. Lu, S. A. Wolf, F. G. Omenetto, X. Zhang, K. A. Nelson, and R. D. Averitt, Terahertz-field-induced insulator-to-metal transition in vanadium dioxide metamaterial, Nature 487, 345 (2012).
[31]S. D. Ha, Y. Zhou, C. J. Fisher, S. Ramanathan, and J. P. Treadway, Abrupt insertion loss drop by RF-triggering of the phase transition in VO2 CPW switches, IEEE. Microw. Wirel. Compon. Lett. 24, 575 (2014).
[32]J. Duchene, M. Terraillon, P. Pailly, and G. Adam, Filamentary conduction in VO2 coplanar thin-film devices, Appl. Phys. Lett. 19, 115 (1971).
[33]J. S. Lee, M. Ortolani, J. Kouba, A. Firsov, Y. J. Chang, T. W. Noh, and U. Schade, Electric-pulse-induced local conducting area and Joule heating effect in VO2/Al2O3 films, Infrared Phys. Technol. 51, 443 (2008).
[34]J. G. Simmons, Poole-Frenkel effect and Schottky effect in metal-insulator-metal systems, Phys. Rev. 155, 657 (1967).
[35]X. Sun, Z. Qu, Y. Yuan, J. Yuan, E. Cheng, P. Wang, J. Hu, and Q. Wang, Role of Joule heating in the electro-induced metal-insular transition of a composite film filled with VO2, Mater. Res. Express 8, 035302 (2021).
[36]K. Fleck, C. La Torre, N. Aslam, S. Hoffmann-Eifert, U. Bottger, and S. Menzel, Uniting gradual and abrupt set processes in resistive switching oxides, Phys. Rev. Appl. 6, 064015 (2016).
[37]H. Lu, M. Lei, C. Zhao, Y. Yao, J. Gou, D. Hui, and Y. Fu, Controlling Au electrode patterns for simultaneously monitoring electrical actuation and shape recovery in shape memory polymer, Compos. B: Eng. 80, 37 (2015).
[38]C. L. Gomez-Heredia, J. A. Ramirez-Rincon, J. Ordonez-Miranda, O. Ares, J. J. Alvarado-Gil, C. Champeaux, F. Dumas-Bouchiat, Y. Ezzahri, and K. Joulain, Thermal hysteresis measurement of the VO2 emissivity and its application in thermal rectification, Sci. Rep. 8, 8479 (2018).
[39]M. Gurvitch, S. Luryi, A. Polyakov, and A. Shabalov, in Future Trends in Microelectronics (Wiley Online Books, 2010), p. 395.
[40] C. Koughia, O. Gunes, C. Zhang, S.-J. Wen, R. Wong, Q. Yang, and S. O. Kasap, Topology of conductive clusters in sputtered high-quality VO2 thin films on the brink of percolation threshold during insulator-to-metal and metalto-insulator transitions, J. Vac. Sci. Technol. A 38, 063401 (2020).
[41] C. Annasiwatta, J. Chen, J. M. Berg, A. Bernussi, Z. Fan, and B. Ren, in 2016 American Control Conference (ACC) (IEEE, Boston, MA, USA, 2016), p. 6905.
[42] S. Wang, J. G. Ramirez, and I. K. Schuller, Avalanches in vanadium sesquioxide nanodevices, Phys. Rev. B 92, 085150 (2015).
[43] G. M. Liao, S. Chen, L. L. Fan, Y. L. Chen, X. Q.Wang, H. Ren, Z. M. Zhang, and C.W. Zou, Dynamically tracking the Joule heating effect on the voltage induced metal-insulator transition in VO2 crystal film, AIP Adv. 6, 045014 (2016).

What is claimed is:

1. A system for sensing radio frequency (RF) signals, the system comprising:
a quantum material film having an electrical resistance; and
a source meter coupled to the quantum material film, wherein the source meter is configured to: (i) measure the electrical resistance of the quantum material film, and (ii) output the measured electrical resistance of the quantum material film, wherein a change in the output of the measured electrical resistance indicates a presence of an RF signal.

2. The system of claim 1, further comprising:
a first electrode and a second electrode deposited on the quantum material film, wherein the first electrode and the second electrode are separated by a distance and the source meter is coupled to the quantum material film via the first electrode and the second electrode.

3. The system of claim 2, wherein the measured electrical resistance is a function of the distance.

4. The system of claim 2, wherein at least one of the first electrode and the second electrode comprises at least one of gold, chromium, titanium, TiN, platinum, and nickel.

5. The system of claim 1, further comprising:
a heating element configured to heat the quantum material film to a configured temperature.

6. The system of claim 5, wherein the measured electrical resistance is a function of the configured temperature.

7. The system of claim 1, wherein the RF signal is between 0.1 gigahertz (GHz) and 100 GHz.

8. The system of claim 1, wherein the quantum material film is at least one of: NdNiO₃, H-doped NdNiO₃, LaNiO₃, SmNiO₃, H-doped SmNiO₃, PrNiO₃, EuNiO₃, Sm-doped NdNiO₃, Sm-doped PrNiO₃, H-doped PrNiO₃, VO₂, Cr-doped VO₂, W-doped VO₂, VOₓ, V₂O₅, V₂O₃, LaCoO₃, Sr-doped LaCoO₃, NbO₂, WO₃, NiO, LaMnO₃, Sr-doped LaMnO₃, and LaTiO₃.

9. The system of claim 1, wherein the quantum material film is between 1 nanometer (nm) and 100 millimeters (mm) thick.

10. The system of claim 1, wherein the quantum material film and source meter are integrated into a portable device.

11. The system of claim 10, wherein the portable device is at least one of: configured to be carried on a person, mounted on a drone, mounted on a vehicle, and mounted on a robot.

12. The system of claim 1, further comprising a plurality of RF sensing devices, wherein each RF sensing device comprises:
a given quantum material film having a given electrical resistance; and
a respective source meter coupled to the given quantum material film wherein the respective source meter is configured to: (i) measure the given electrical resistance of the given quantum material film and (ii) output the measured given electrical resistance of the given quantum material film, wherein a change in the output of the measured given electrical resistance indicates a presence of one or more RF signals.

13. The system of claim 12, further comprising:
a processor; and
a memory with computer code instructions stored thereon, the processor and the memory with the computer code instructions stored thereon, being configured to cause the system to analyze, via a machine learning engine, each measured given electrical resistance.

14. The system of claim 13, wherein a result of the analyzing is at least one of: an indication of frequency of the one or more RF signals, an indication of signal strength of the one or more RF signals, an indication of direction of the one or more RF signals, and an indication of spectrum of the one or more RF signals.

15. The system of claim 1, further comprising:
a processor; and
a memory with computer code instructions stored thereon, the processor and the memory with the computer code instructions stored thereon, being configured to cause the system to analyze, via a machine learning engine, the output measured electrical resistance.

16. The system of claim 15, wherein a result of the analyzing is at least one of: an indication of frequency of the RF signal, an indication of signal strength of the RF signal, an indication of direction of the RF signal, and an indication of spectrum of the RF signal.

17. A method for sensing radio frequency (RF) signals, the method comprising:
receiving one or more signals at a quantum material film having an electrical resistance;
measuring, using a source meter coupled to the quantum material film, the electrical resistance of the quantum material film; and
outputting, from the source meter, the measured electrical resistance of the quantum material film, wherein a change in the output of the measured electrical resistance indicates a presence of an RF signal from amongst the one or more signals.

18. The method of claim 17 further comprising:
configuring a distance between a first electrode and a second electrode deposited on the quantum material film, wherein the source meter is coupled to the quantum material film via the first electrode and the second electrode.

19. The method of claim 17, further comprising heating the quantum material film to a configured temperature.

20. The method of claim 17, further comprising deploying a plurality of RF sensing devices, wherein each deployed RF sensing device is configured to:
receive one or more respective signals at a given quantum material film having a given electrical resistance;
measure, using a respective source meter coupled to the given quantum material film, the given electrical resistance of the given quantum material film; and
output, from the respective source meter, the measured given electrical resistance of the given quantum material film, wherein a change in the output of the measured given electrical resistance indicates a presence of at least one RF signal amongst the one or more respective signals.
